(19) United States
(12) Patent Application Publication
(10) Pub. No.: US 2026/0033306 A1
(43) Pub. Date: Jan. 29, 2026

(54) PROTECTION OF SENSITIVE SURFACES IN SEMICONDUCTOR PROCESSING

(71) Applicant: Lam Research Corporation, Fremont, CA (US)

(72) Inventors: Diane HYMES, San Jose, CA (US); Jon HENRI, West Linn, OR (US); Lee J. BROGAN, Newberg, OR (US); Oluwadamilola Sanyaolu PHILLIPS, Hayward, CA (US); Zhengtao CHEN, Leuven (BE)

(21) Appl. No.: 19/123,361

(22) PCT Filed: Oct. 24, 2023
(86) PCT No.: PCT/US2023/077687

§ 371 Date: Apr. 22, 2025

Related U.S. Application Data
(60) Provisional application No. 63/380,828, filed on Oct. 25, 2022.

(51) Int. Cl. H01L 21/768; C23C 14/04; C23C 14/14; C23C 16/06; C23C 16/455; C23C 28/02; C25D 5/02

(52) U.S. Cl. CPC H01L 21/76831; C23C 14/046; C23C 14/14; C23C 16/06; C23C 16/45525; C23C 28/023; C25D 5/02; H01L 21/76843; H01L 21/76873; H01L 21/76879; H01L 2221/1063

(57) ABSTRACT

Methods and apparatus for transient protection of a sensitive surface of a substrate are described. Methods that facilitate transient protection of a sensitive surface of substrate include depositing a sacrificial capping layer on a sensitive surface of the substrate after a processing operation. The capping layer deposition and the prior processing operation occur under vacuum. In some embodiments, for example, the capping layer deposition and the prior processing operation occur in different modules of a tool connected by a vacuum transfer chamber. In other embodiments, the capping layer deposition and the prior processing operation occur in the same module Methods that facilitate transient protection of a sensitive surface of substrate include removing the capping layer from the sensitive surface of the substrate prior to a subsequent processing operation. The removal is performed without damaging the sensitive surface or underlying layers of the semiconductor substrate.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

During semiconductor fabrication, many surfaces are sensitive to airborne molecular contaminants (AMCs) in the surrounding environment. Queue time can lead to exposure to the AMCs and unwanted interactions such as oxidation, corrosion, and halogenation. Solutions include storing partially fabricated semiconductor substrates in nitrogen (N₂)-filled storage cassettes or rooms and using integrated tools that support multiple processes without breaking the vacuum on the substrates. These solutions are difficult and expensive to implement and pose safety and reliability concerns.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods, apparatus, and systems for semiconductor processing that facilitate transient protection of a sensitive surface of substrate. According to various embodiments, the methods include depositing a sacrificial capping layer on a sensitive surface of the substrate after a processing operation. The capping layer deposition and the prior processing operation occur under vacuum. In some embodiments, for example, the capping layer deposition and the prior processing operation occur in different modules of a tool connected by a vacuum transfer chamber. In other embodiments, the capping layer deposition and the prior processing operation occur in the same module. Also, according to various embodiments, the methods, apparatus, and systems include removing the capping layer from the sensitive surface of the substrate prior to a subsequent processing operation. The removal is performed without damaging the sensitive surface or underlying layers of the semiconductor substrate. In some embodiments, the removal and the subsequent processing operation occur under vacuum. In some embodiments, for example, the capping layer removal and the subsequent processing operation occur in different modules of a substrate processing tool connected by a vacuum transfer chamber. In other embodiments, the capping layer removal and the subsequent processing operation occur in the same module. In other embodiments, the removal and/or subsequent processing operation occur at atmospheric pressures.

One aspect of the disclosure relates to a method including providing a substrate including a patterned dielectric structure to a first processing apparatus, depositing one or more conformal layers on the patterned dielectric structure; and depositing a protective capping layer on the one or more conformal layers, wherein deposition of the one or more conformal layers and deposition of the protective capping layer are performed without exposing the substrate to ambient conditions during or between the deposition operations.

In some embodiments, depositing the one or more conformal layers and depositing the protective capping layer are performed in the first processing apparatus.

In some embodiments, the first processing apparatus is a multi-module apparatus including a plurality of modules connected by a substrate transfer chamber. In some such embodiments, deposition of at least one of the one or more conformal layers and deposition of the protective capping layer are performed in the same module of the first processing apparatus. In some such embodiments, deposition at least one of the one or more conformal layers and deposition of the protective capping layer are performed in the different modules of the first processing apparatus.

In some embodiments, the one or more conformal layers include a diffusion barrier layer.

In some such embodiments, the diffusion barrier is selected from a tantalum nitride layer, a titanium nitride layer, a tungsten nitride layer, a tungsten carbon nitride layer, a zinc oxide layer, and a tin oxide layer.

In some embodiments, the one or more conformal layers include a metal seed layer. In some such embodiments, the metal seed layer is a cobalt layer.

In some embodiments, the protective capping layer is a stimulus responsive polymer (SRP), the SRP characterized by a ceiling temperature (T_{c}) at which the SRP is in thermal equilibrium with its monomers, the Tc being between −80° C. and 400° C.

In some embodiments, the one or more conformal layers is deposited by atomic layer deposition (ALD). In some embodiments, the protective capping layer is deposited by chemical vapor deposition (CVD).

In some embodiments, the method further includes transferring the substrate from the first processing apparatus after the protective capping layer is deposited.

In some embodiments, the method further includes transferring the substrate to a second processing apparatus; and removing the protective capping layer in the second processing apparatus.

In some embodiments, patterned dielectric structure includes a recessed feature and the method further includes filling the recessed feature with metal after removing the protective capping layer. In some embodiments, filling the recessed feature with metal includes a physical vapor deposition (PVD) reflow process.

In some embodiments, the protective capping layer is an oxide, a nitride, or a carbide layer. In some embodiments, the protective capping layer is deposited on a metal seed layer. In some embodiments, the patterned dielectric structure includes a recessed feature and further comprising filling the recessed feature with metal after removing the protective capping layer. In some embodiments, filling the recessed feature with metal includes an electroplating process. In some embodiments, the removal of the protective capping layer is achieved by thermal desorption above an immersion bath in an electroplating chamber or liquid dissolution in an immersion bath in an electroplating chamber.

Another aspect of the disclosure relates to a method including: providing a substrate including a recessed feature to a first processing apparatus, the substrate including a protective capping layer overlying the recessed feature; and removing the protective capping layer; and filling the recessed feature with metal, wherein the removal of the protective capping layer and filling the recessed feature with metal are performed without exposing the substrate to ambient conditions during or between the removal and filling operations.

In some embodiments, the protective capping layer includes a stimulus responsive polymer (SRP), the SRP characterized by a ceiling temperature (T_{c}) at which the SRP is in thermal equilibrium with its monomers, the Tc being between −80° C. and 400° C. In some embodiments, removing the protecting capping layer includes heating the substrate to a temperature above the Tc.

In some embodiments, filling the recessed feature with metal includes a physical vapor deposition (PVD) reflow process.

In some embodiments, the protective capping layer is an oxide, a nitride, or a carbide layer. In some embodiments, the protective capping layer is deposited on a metal seed layer. In some embodiments, the patterned dielectric structure includes a recessed feature and further comprising filling the recessed feature with metal after removing the protective capping layer. In some embodiments, filling the recessed feature with metal includes an electroplating process. In some embodiments, the removal of the protective capping layer is achieved by thermal desorption above an immersion bath in an electroplating chamber or liquid dissolution in an immersion bath in an electroplating chamber.

Another aspect of the disclosure relates to an apparatus including a first module configured for depositing one or more conformal layers on a patterned dielectric structure on a substrate; a second module configured for depositing a protective capping layer on the one or more conformal layers; and a vacuum transfer chamber for transferring the substrate from the first module to the second module exposing the substrate to ambient conditions.

Another aspect of the disclosure relates to an apparatus including: a first module configured for removing a protective capping layer from a patterned structure; a second module configured for filling a feature of the patterned structure with metal; and a vacuum transfer chamber for transferring the substrate from the first module to the second module exposing the substrate to ambient conditions.

These and other aspects of the disclosure are described below with reference to the drawings.

### BRIEF DESCRIPTION OF DRAWINGS

FIG. 1A is a functional block diagram of an example of a substrate processing system including multiple substrate processing tools and a storage buffer.

FIG. 1B shows an example of a substrate processing module for depositing the polymer film on a substrate.

FIG. 2 is a flow diagram showing certain operations in a method of depositing a stimulus responsive polymer (SRP) film on a substrate.

FIG. 3 is a flow diagram showing examples of operations for SRP removal according to various embodiments.

FIG. 4 shows an example a remote plasma processing module that may be used for ALD deposition.

FIG. 5 shows an example of an electroplating cell that may be used for pre-capping or post-capping processing according to various embodiments.

FIG. 6 shows an example of a physical vapor deposition (PVD) module that may be used for pre-capping or post-capping processing according to various embodiments.

FIG. 7 illustrates various operations in a method of preparing a substrate for metal fill according to various embodiments.

FIGS. 8A and 8B illustrate various operations in examples of methods for metal fill according to various embodiments.

### DETAILED DESCRIPTION

Provided herein are methods, apparatus, and systems for semiconductor processing that facilitate transient protection of a sensitive surface of substrate. According to various embodiments, the methods include depositing a sacrificial capping layer on a sensitive surface of the substrate after a processing operation. The capping layer deposition and the prior processing operation occur under vacuum. In some embodiments, for example, the capping layer deposition and the prior processing operation occur in different modules of a tool connected by a vacuum transfer chamber. In other embodiments, the capping layer deposition and the prior processing operation occur in the same module. Also, according to various embodiments, the methods, apparatus, and systems include removing the capping layer from the sensitive surface of the substrate prior to a subsequent processing operation. The removal is performed without damaging the sensitive surface or underlying layers of the semiconductor substrate. In some embodiments, the removal and the subsequent processing operation occur under vacuum. In some embodiments, for example, the capping layer removal and the subsequent processing operation occur in different modules of a substrate processing tool connected by a vacuum transfer chamber. In other embodiments, the capping layer removal and the subsequent processing operation occur in the same module. In other embodiments, the removal and/or subsequent processing operation occur at atmospheric pressures.

Between capping layer deposition and removal, the semiconductor substrate may be removed from vacuum and exposed to the surrounding environment. During semiconductor fabrication, many surfaces are sensitive to airborne molecular contaminants in the surrounding environment. Queue time can lead to exposure to these contaminants and unwanted interactions such as oxidation, corrosion, and halogenation. The capping layer protects the sensitive surface of the semiconductor substrate from the surrounding environment. According to various embodiments, the sacrificial capping layer may be effective to protect the sensitive substrate for at least 5-10 hours.

While deposition and removal of capping layers is described herein chiefly in the context of surface protection, the methods and systems for deposition and/or removal described herein are not so limited. For example, the deposited material may also be used for other purposes in addition to or instead of surface protection. These purposes can include deposition into features for temporary structural support or as capping layers for other purposes.

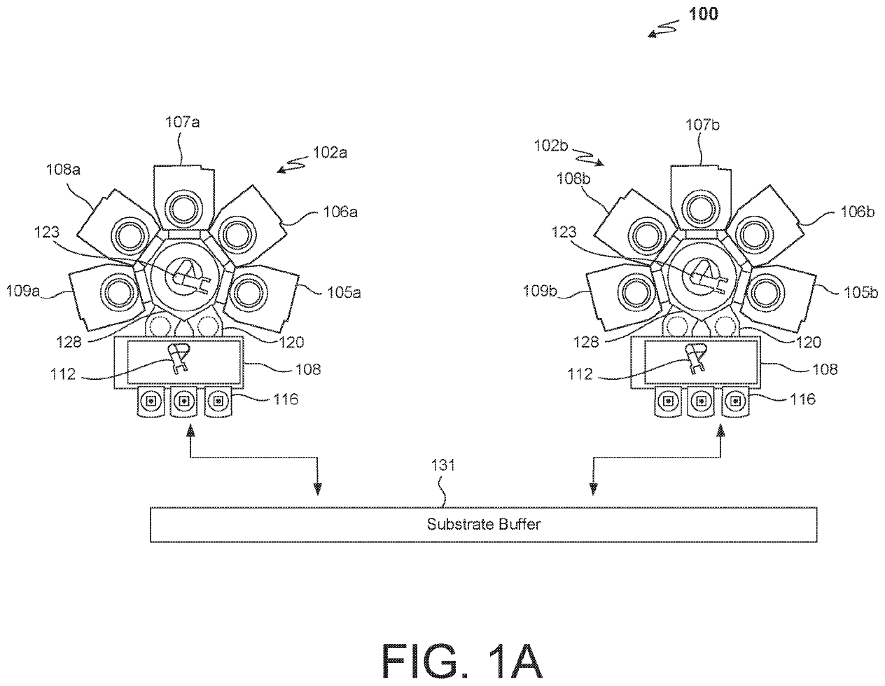

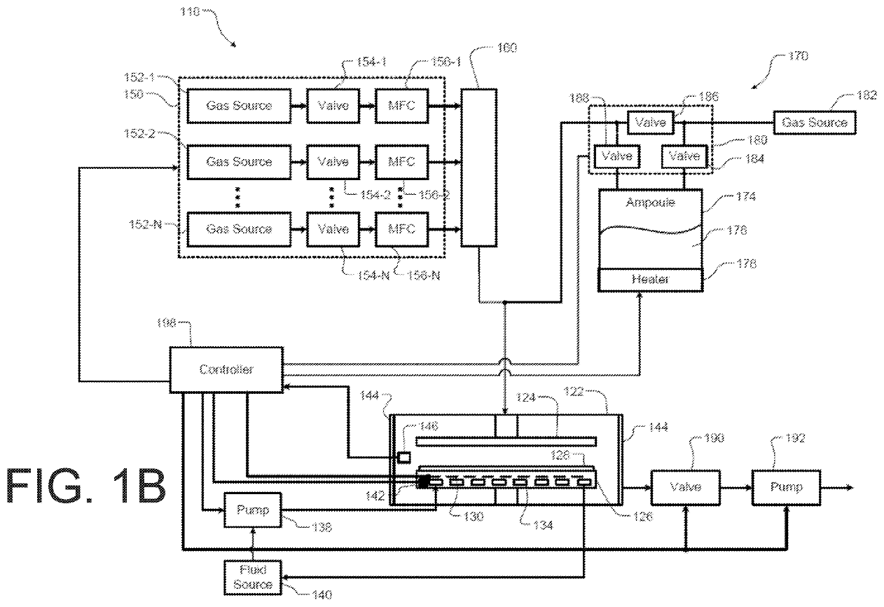

FIG. 1A is a functional block diagram of an example of a substrate processing system including multiple substrate processing tools and a storage buffer according to the present disclosure. Substrate processing system 100 includes one or more substrate processing tools (substrate processing tools 102a and 102b are shown for illustration purposes) and substrate buffer 131 or other substrate storage. Substrate processing tool 102a includes a plurality of processing modules 105a, 106a, 107a, 108a, and 109a. Substrate processing tool 102b includes a plurality of processing modules 105b, 106b, 107b, 108b, and 109b.

For example, each of the processing modules 105a-109a may be configured to perform a substrate treatment. In some examples, a substrate may be loaded into one of the processing modules, processed, and then moved to one or more other ones of the processing modules, and/or removed from the substrate processing tool 102a.

In the example of FIG. 1A, substrates to be processed are loaded into the substrate processing tool 102a via ports of loading stations 116 of a transfer module 108. The substrates are then transferred into one or more of the processing modules 105a-109a. For example, a transfer robot 112 in the transfer module 108 is arranged to transfer substrates from loading stations 116 to load locks 120. A vacuum transfer robot 123 of a vacuum transfer module 128 is arranged to transfer substrates from the load locks 120 to the various processing modules 105a-109a.

After processing in the substrate processing tools 102a, the substrates may be transported outside of a vacuum environment. For example, the substrates may be moved to a location for storage (such as the substrate buffer 131). In other examples, the substrates may be moved directly from the substrate processing tool to another substrate processing tool for further processing. In some embodiments, one or more of the processing modules 105a-109a is used to deposit sacrificial capping layers deposited on the substrates prior to transport outside of the vacuum environment.

In the example of FIG. 1A, substrates to be processed are loaded into the substrate processing tool 102b via ports of loading stations 116 of a transfer module 108. The substrates are then transferred into one or more of the processing modules 105b-109b. For example, a transfer robot 112 in the transfer module 108 is arranged to transfer substrates from loading stations 116 to load locks 120. A vacuum transfer robot 123 of a vacuum transfer module 128 is arranged to transfer substrates from the load locks 120 to the various processing modules 105b-109b.

In some embodiments, one or more of the processing modules 105a-109a is used to remove sacrificial capping layers deposited on the substrates after transport back into a vacuum environment. In some embodiments, one or more load locks 120 may be used to remove sacrificial capping layers once under vacuum.

The removal process is one that does not damage the sensitive surface or underlying layers of the semiconductor substrate. Depending on the particular surface and layers of the substrate, the removal process may involve exposure to heat, UV radiation, liquid or gas chemical treatment, or plasma, for example. In some embodiments, removal conditions such as high temperatures, aggressive plasmas, and exposure to oxidizing conditions are Removal processes that may be used according to various embodiments are described further below.

Examples of processing operations that may be performed prior to deposition of a sacrificial capping layer include deposition processes, etch processes, lithographic processes, planarization processes, and the like. In some embodiments, for example, the prior processing includes thin film deposition with the sacrificial layer deposited on the thin film.

Examples of processing operations that may be after removal of a sacrificial capping layer include deposition processes, etch processes, lithographic processes, planarization processes, and the like. In some embodiments, for example, the subsequent processing includes metal fill.

### Sacrificial Capping Layers

Examples of sacrificial capping layers include alumina (Al₂O₃), aluminum nitride (AINₓ), metal silicides formed on a layer of the metal (e.g., cobalt silicide formed on a cobalt layer), other metal silicides, metal oxides formed on a layer of the metal (e.g., cobalt oxide formed on a cobalt layer under controlled process conditions), other oxides, metal nitrides formed on a layer of the metal, other nitrides, metal carbides formed on a layer of the metal, and other carbides. Specific examples include zinc oxide (ZnO), boron (B), boron oxide (B₂O₃), boron nitride (BN), a metal-aluminum alloy formed on a layer of the metal (e.g., CoAl formed on a cobalt layer), graphene, films of small molecules, and stimulus responsive polymers (SRPs).

Forming an alumina layer can involve exposing a surface to trimethylaluminum (TMA) or other aluminum-containing reactant and water (H₂O) an oxygen-containing reactant in a thermal deposition process. Forming an AlNₓ layer can involve exposing the surface to TMA or other aluminum-containing reactant and ammonia (NH₃) or other nitrogen-containing reactant in a thermal deposition process. Forming a metal silicide can involve exposing a metal surface to silane (SiH₄) in a thermal deposition process. Forming a B or B₂O₃ layer can involve exposing a surface to a boron-containing reactant such as diborane (B₂H₆) and an in-situ capacitively-coupled plasma generated from hydrogen (H₂) gas. Forming a BN film can involve exposing a surface to a boron-containing reactant such as diborane and an in-situ capacitively-coupled plasma generated from ammonia (NH₃) gas. Forming a metal-aluminum alloy formed on a layer of the metal can involve exposing the metal to TMA with or without a remote plasma or in-situ capacitively-coupled plasma generated from hydrogen gas.

Forming a small molecule film or an SRP film can involve vapor deposition, as described further below. Forming an oxide, nitride, or carbide film can involve vapor deposition as described further below.

In some embodiments, removal of a sacrificial capping layer involves a dry process such as an atomic layer etch (ALE) process. For example, ALE may be used to remove alumina or aluminum nitride films. In some embodiments, removal of a sacrificial capping layer involves a wet process such an acid bath removal. For example, an acid bath may be used to remove alumina, zinc oxide, B, small molecule, SRP, and B₂O₃ films. In some embodiments, removal of a sacrificial capping layer involves a dry process such exposure to heat, UV, or plasma. For example, removal of small molecule and SRP films can involve exposure to a stimulus that induces evaporation or sublimation. In some embodiments, removal of a sacrificial capping layer can involve a mechanical method such as peel-off, in which the sacrificial capping layer is attached by adhesive to another substrate, while the first substrate remains chucked or affixed to some kind of holder.

Removal of oxide, nitride, carbide, small molecule, and SRP films are also described further below.

### Small Molecule Films as Sacrificial Capping Layers

Forming small molecule films for surface protection is described in PCT patent application Ser. No. 20/210,46061WO, which is incorporated by reference herein. In some embodiments, this may involve exposing the surface to a vapor including the small molecules such that they condense on the surface to form the film. Non-limiting methodologies of forming a film include vapor-based deposition, such as chemical vapor deposition; and solvent-based deposition, such as spin-coating, drop-casting, or solvent-casting. Vapor-based deposition may be used in some embodiments of the methods, systems, and apparatus described herein as more easily integrated with upstream substrate processing operations. As described further below, in some embodiments, a stimulus may be applied to convert the molecule to a less volatile form for stability.

The small molecules may have relatively low vapor pressure at room temperature; in some embodiments, it less than about 1×10⁻⁴ atm or less than about 76 mTorr. The small molecules are solid at atmospheric pressure and room temperature (about 20° C.-25° C.). The small molecules are further characterized by having a vapor pressure of at least 10 Torr at a temperature higher than 20° C. below about 400° C. Examples of such small molecules include fused aromatic rings such as naphthalene and anthracene.

The film of small molecules may have a non-negligible vapor pressure once on the substrate, potentially contaminating the loading stations or other storage units, or contaminating the wafer backside during queue time. Thus, a chemical or physical switch may be incorporated into the molecule such that once on the substrate, it becomes significantly less volatile than in its initial form and is locked into place. Prior to removal, the molecules can be converted to the more volatile form. Examples of reversible chemical reactions that may be performed to convert the monomer to a less volatile form include photoisomerization of a molecule such as stilbene from trans to cis, photodimerization, and a combination reaction such as a Diels-Alder reaction.

In a specific example, dimerization of anthracene uses UV light to go forward (e.g., UV light above 300 nm, which can promote photo-cycloaddition to promote dimerization). It is reversible prior to removal with the trigger of heat or additional UV light of a higher energy, such as UV light below 300 nm (e.g., which can reverse the photo-cycloaddition reaction, thus producing monomers).

In some embodiments, a Diels-Alder reaction is used to convert a film of small molecules to a less volatile form. For example, cyclopentadiene reacts spontaneously at room temperature to yield dicyclopentadiene, and reverts back to cyclopentadiene at temperatures above approximately 125° C. Addition of heat can thermally reverse the cycloaddition reaction, thereby producing the initial reactants.

Other photodimerization, photopolymerization, photoisomerization, and Diels-Alder reactions can be employed with small molecules useful for conducting such reactions, as described herein.

Photodimerization and photopolymerization can include, for instance, optionally substituted anthracene or optionally substituted naphthalene. Optional substitutions for such compounds can include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl (—CO₂H), carboxyalkyl, carboxyaldehyde (—C(O)H), alkoxy, aryloxy, alkanoyl (e.g., —C(O)—R, in which R is alkyl), aryloyl (e.g., —C(O)—R, in which R is aryl), alkanoyloxy (e.g., —O—C(O)—R, in which R is alkyl), aryloyloxy (e.g., —O—C(O)—R, in which R is aryl), alkoxycarbonyl (e.g., —C(O)—OR, in which R is alkyl), aryloxycarbonyl (e.g., —C(O)—OR, in which R is aryl), and/or

Photoisomerization, as well as photodimerization and photopolymerization reactions, can be employed with stilbene or derivatives thereof. Optional substitutions for such compounds can include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl, carboxyalkyl, carboxyaldehyde, alkoxy, aryloxy, alkanoyl, aryloyl, alkanoyloxy, aryloyloxy, alkoxycarbonyl, aryloxycarbonyl, and/or oxo.

Diels-Alder reactions may be performed by employing a diene (or a diyne) and a dienophile (or a diynophile) to provide a cyclic derivative. Non-limiting dienes include a cyclic or acyclic compound having two or more double bonds, such as those having a 4π electron system, including an optionally substituted 1,3-unsaturated compound (e.g., optionally substituted 1,3-butadiene, optionally substituted cyclopentadiene, optionally substituted cyclohexadiene, optionally substituted furan, optionally substituted thiofuran, or optionally substituted imine) or an optionally substituted benzene. Non-limiting diynes include a cyclic or acyclic compound having two or more triple bonds, such as an optionally substituted 1,3-butadiyne. Non-limiting dienophiles, heterodienophiles, and diynophiles having a 2π electron system include an optionally substituted alkene, optionally substituted alkyne, optionally substituted ketone, optionally substituted aldehyde, optionally substituted heteroalkene, optionally substituted imine, optionally substituted benzene, optionally substituted cycloalkene, and optionally substituted cycloheteroalkene.

The cyclic derivative can include, e.g., an optionally substituted cycloalkene (e.g., optionally substituted cyclohexene or optionally substituted 1,4-cyclohexadiene), optionally substituted dihydropyran (e.g., optionally substituted 3,6-dihydro-2H-pyran), optionally substituted tetrahydropyridine (e.g., optionally substituted 1,2,3,6-tetrahydropyridine), optionally substituted benzene, optionally substituted dihydronaphthalene, optionally substituted norbornene, optionally substituted heteronorbornene, optionally substituted benzonorbornene, optionally substituted heterocycle, optionally substituted carbocycle, or optionally substituted dicyclopentadiene.

The diene, diyne, dienophile, diynophile, and cyclic derivative can include one or more optional substitutions, such as any described herein for alkyl and aryl. In other embodiments, optional substitutions for such compounds include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl, carboxyalkyl, carboxyaldehyde, alkoxy, aryloxy, alkanoyl, aryloyl, alkanoyloxy, aryloyloxy, alkoxycarbonyl, aryloxycarbonyl, oxo, trialkylsilyl (e.g., —SiR₃, in which R is alkyl as defined herein), or trialkylsilyloxy (e.g., —OSiR₃, in which R is alkyl as defined herein).

Removing a sacrificial capping layer can involve exposing to a stimulus, such as heat and/or light, that induces sublimation or evaporation. In some embodiments, a stimulus may be applied to convert the molecule to a more volatile form for easy removal. In some embodiments, a chemical removal may be used.

### SRPs as Sacrificial Capping Layers

SRPs as described herein are polymers that are in thermal equilibrium with their constituent monomers at a ceiling temperature (Tc). On exposure to an appropriate stimulus, an SRP is de-polymerized with the monomer products easily removed from the surface of the substrate. The ceiling temperature is an intrinsic property of the polymer. According to various embodiments, the SRPs have ceiling temperatures between −80° C. and 400° C.

In many embodiments, the SRPs are low ceiling temperature (Tc) polymers. As used herein, the term low Tc refers to Tc values below a removal temperature. In some embodiments, the Tc is below room temperature, such that the polymers are thermodynamically unstable at room temperature. Instead, the low Tc polymer is kinetically trapped to allow prolonged storage at room temperature. In some examples, the stable storage period is on the order of months or years. Low Tc polymers will rapidly de-polymerize to its monomer constituents if an end-group or main chain bond is broken. Thus, the polymer de-polymerizes in response to stimuli such as ultraviolet (UV) light, heat, thermal catalyst, photocatalyst, noble gas plasma, or an acidic/basic catalyst. The monomer products are volatile and leave or can be easily removed from the surface and chamber.

While in some embodiments, the Tc is below room temperature, in the context of semiconductor processing, low Tc may also refer to ceiling temperatures that are higher than room temperature. For example, removal temperatures of up to 400° C. may be used, meaning that the ceiling temperature is below 400° C. In some embodiments, the SRP is characterized by having a Tc below 200° C. In some embodiments, the SRP is characterized by having a Tc between −80° C. and 200° C., between −80° C. and 150° C., or between −80° C. and 100° C. In some embodiments, having a ceiling temperature of no more than about 100° C. is advantageous such that de-polymerization into constituent monomers can occur without burning or charring the SRP.

For low-Tc polymer systems, the glass transition often occurs at a higher temperature than the degradation temperature. As discussed further below, adding plasticizer can depress the glass transitions temperature below the degradation temperature of an amorphous polymer system.

Examples of SRPs are provided below. However, the methods described herein may be used with any SRPs. In some embodiments, the SRPs are co-polymers or homopolymers including poly(aldehydes). Non-limiting examples of homopolymer or constituent polymers of a copolymer in SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a polyglyoxylamide, a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

In some embodiments, the SRP is a homopolymer. Such a polymer can be a linear polymer and have any useful number n of monomers, such as n is from about 2 to about 100,000. In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives.

Examples of SRPs are provided below. However, the methods described herein may be used with any SRPs. In some embodiments, the SRPs are homopolymers including poly(aldehydes). SRPs can be any appropriate homopolymer in linear or cyclic form. Non-limiting SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a poly(glyoxylamide), a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

Yet other SRPs can include those having a structure of one of formulas (I)-(XV), (Ia), (Ib), or (Ic). Such SRPs can be a linear polymer or a cyclic polymer. If linear, the polymer can include any useful end groups that terminate the molecule. Such end groups can depend on the reactive end groups present on the monomers employed to synthesize the polymer. In particular embodiments, end groups can include those fragments formed from use of an anionic initiator (e.g., fragments such as alkyl anion, e.g., present in n-BuLi, s-BuLi, etc.), from use of an acylation or alkylation reagent (e.g., fragments such as acyl or optionally substituted alkanoyl, such as formyl, acetyl, benzoyl, methyl, ethyl, etc.), from use of a conjugated alkylene monomer (e.g., such as a quinone methide monomer), or from use of an alcohol termination agent (e.g., fragments such as optionally substituted alkoxy). The end groups can include any useful binding group or a reactive group (e.g., those including optionally substituted trialkylsiloxy, optionally substituted alkenyl, optionally substituted aryl, etc.).

The SRP can include a poly(phthalaldehyde) or a derivative thereof, which can be a homopolymer that is linear or cyclic. In one embodiment, the SRP is or includes a structure of formula (I):

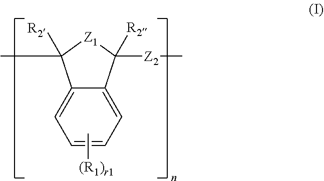

or a salt thereof, wherein
each R₁ is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, optionally substituted heteroalkyl, or optionally substituted aryl;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (I)), each of R_{2′} and R_{2″} is, independently, H or optionally substituted alkyl. In some embodiments, each of Z₁ and Z₂ is —O—.

The SRP can include a poly(aldehyde) or a derivative thereof, which can be a homopolymer that is linear or cyclic. In one embodiment, the SRP is or includes a structure of formula (II):

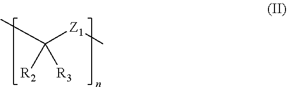

or a salt thereof, wherein:
each of R₂ and R₃ is, independently, H, optionally substituted alkyl, optionally substituted heteroalkyl, or optionally substituted aryl;
Z₁ is —O—, —S—, or optionally substituted heteroalkylene; and
n is from about 2 to about 100,000.

The SRP can include a poly(benzyl carbamate) or a derivative thereof, which can be a homopolymer that is linear or cyclic. In one embodiment, the SRP is or includes a structure of formula (III):

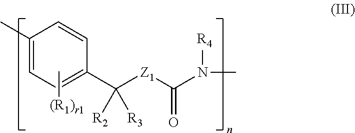

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
R₄ is H or optionally substituted alkyl;
Z₁ is —O—, —S—, or optionally substituted heteroalkylene;
r1 is an integer from 1 to 4; and
n is from about 2 to about 100,000.

In particular embodiments (e.g., of formula (III)), Ri is optionally substituted alkoxy. In other embodiments, n is from about 2 to about 100 (e.g., from about 2 to 10, 2 to 15, 2 to 20, 2 to 25, 2 to 30, 2 to 40, 2 to 50, 2 to 75, 4 to 10, 4 to 15, 4 to 20, 4 to 25, 4 to 30, 4 to 40, 4 to 50, 4 to 75, and 4 to 100).

The SRP can include a poly(benzyl ether) or a derivative thereof, which can be a homopolymer that is linear or cyclic. In one embodiment, the SRP is or includes a structure of

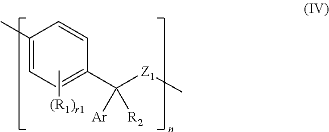

or a salt thereof, wherein:
each R₁ is, independently, H, optionally substituted alkyl, optionally substituted alkoxy, optionally substituted alkenyl, optionally substituted aryl, or halo;
R₂ is H, optionally substituted alkyl, optionally substituted heteroalkyl, or optionally substituted aryl;
Ar is optionally substituted aryl, optionally substituted alkyl, or optionally substituted aralkyl;
Z₁ is —O—, —S—, or optionally substituted heteroalkylene;
r1 is an integer from 1 to 4; and
n is from about 2 to about 100,000.

In particular embodiments (e.g., of formula (IV)), Ri is optionally substituted alkyl. In other embodiment, Ar is optionally substituted phenyl. In other embodiments, n is from about 2 to about 5000.

The SRP can include a poly(benzyl dicarbamate) or a derivative thereof, which can be a homopolymer that is linear or cyclic. In one embodiment, the SRP is or includes a structure of formula (V):

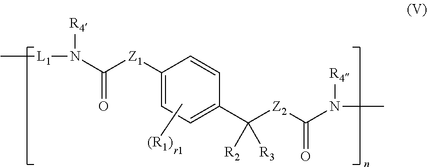

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
each of R_{4′} and R_{4″} is, independently, H or optionally substituted alkyl;
L₁ is optionally substituted alkylene, optionally substituted heteroalkylene, optionally substituted arylene, or optionally substituted cycloalkylene;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (V)), R₁ is optionally substituted alkyl. In other embodiment, Ar is optionally substituted phenyl. In other embodiments, n is from about 2 to about 5000. In other embodiments (e.g., of formula (V)), each of R_{4′} and R_{4″} is, independently, optionally substituted alkyl. In some embodiments, L₁ is optionally substituted alkylene. In other embodiments, Z₁ and Z₂ is —O—.

The SRP can include a poly(dicarbamate) or a derivative thereof, which can be a homopolymer that is linear or cyclic. In one embodiment, the SRP is or includes a structure of

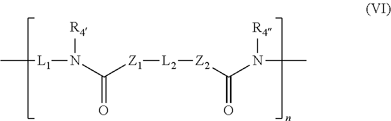

or a salt thereof, wherein:
each of R_{4′} and R_{4″} is, independently, H or optionally substituted alkyl;
each of L₁ and L₂ is, independently, optionally substituted alkylene, optionally substituted heteroalkylene, optionally substituted arylene, or optionally substituted cycloalkylene, in which L₂ can optionally be a covalent bond;
each of Z₁ and Z₂ is, independently, —O—, —S—, or optionally substituted heteroalkylene; and
n is from about 2 to about 100,000.

In particular embodiments (e.g., of formula (VI)), each of R_{4′} and R_{4″} is, independently, optionally substituted alkyl. In some embodiments, each of L₁ and L₂ is, independently, optionally substituted alkylene. In other embodiments, each of Z₁ and Z₂ is, independently, —O— or —S—.

The SRP can include a poly(alpha-methyl styrene) or a derivative thereof, which can be a homopolymer that is linear or cyclic. In one embodiment, the SRP is or includes a structure of formula (VII):

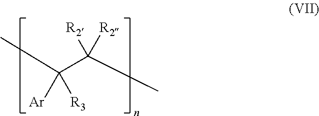

or a salt thereof, wherein:
each of R_{2′}, R_{2″}, and R₃ is, independently, H, optionally substituted alkyl, optionally substituted heteroalkyl, or optionally substituted aryl;
Ar is optionally substituted aryl, optionally substituted alkyl, or optionally substituted aralkyl; and
n is from about 2 to about 100,000.

The SRP can include a poly(carbonate) or a derivative thereof, which can be a homopolymer that is linear or cyclic. In one embodiment, the SRP is or includes a structure of formula (VIII):

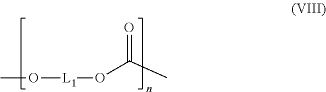

or a salt thereof, wherein:
L₁ is optionally substituted alkylene, optionally substituted heteroalkylene, optionally substituted arylene, or optionally substituted cycloalkylene; and
n is from about 2 to about 100,000.

In particular embodiments (e.g., of formula (VIII)), L₁ is optionally substituted alkylene, optionally substituted heteroalkylene, or optionally substituted cycloalkylene. In some embodiments, the optionally substituted heteroalkylene is —X-Ak-X—, in which X is oxy and Ak is optionally substituted alkylene. Non-limiting SRPs can include poly(ethylene carbonate), poly(propylene carbonate) (PPC), poly(butylene carbonate) (PBC), poly(cyclohexene carbonate) (PCHC), poly(norbornene carbonate) (PNC), and poly(cyclohexene propylene carbonate) (PCPC).

The SRP can include a poly(norbornene) or a derivative thereof, which can be a homopolymer that is linear or cyclic. In one embodiment, the SRP is or includes a structure of formula (IX):

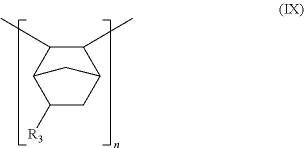

or a salt thereof, wherein:
R₃ is H, optionally substituted alkyl, optionally substituted heteroalkyl, or optionally substituted aryl; and
n is from about 2 to about 100,000.

The SRP can include a poly(olefin sulfone) or a derivative thereof, which can be a homopolymer that is linear or cyclic. In one embodiment, the SRP is or includes a structure of formula (X):

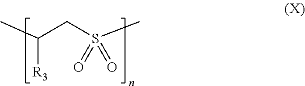

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (X)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

The SRP can include a poly(glyoxylate) or a derivative thereof, which can be a homopolymer that is linear or cyclic. In one embodiment, the SRP is or includes a structure of formula (XI):

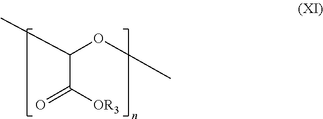

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (XI)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl.

The SRP can include a poly(methyl methacrylate) or a derivative thereof, which can be a homopolymer that is linear or cyclic. In one embodiment, the SRP is or includes a structure of formula (XII):

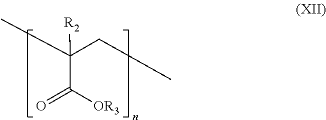

or a salt thereof, wherein:
each of R₂ and R₃ is, independently, H, optionally substituted alkyl, optionally substituted heteroalkyl, or optionally substituted aryl; and
n is from about 2 to about 100,000.

In particular embodiments (e.g., of formula (XII)), R₂ is optionally substituted alkyl. In other embodiments (e.g., of formula (XII)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl.

The SRP can include a poly(glyoxylamide) or a derivative thereof, which can be a homopolymer that is linear or cyclic. In one embodiment, the SRP is or includes a structure of formula (XIII):

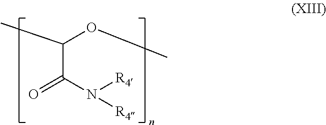

or a salt thereof, wherein:
each of R_{4′} and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein; and
n is from about 2 to about 100,000.

In particular embodiments (e.g., of formula (XIII)), each of R_{4′} and/or R_{4″} is optionally substituted alkyl, optionally substituted heteroalkyl, or optionally substituted aminoalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl. In other embodiments, R_{4′} is H or alkyl, and R_{4″} is optionally substituted alkyl, optionally substituted heteroalkyl, or optionally substituted aminoalkyl (e.g., as described above). In yet other embodiment, R_{4′}, and R_{4″}, taken together with the nitrogen atom to which each are attached, form a heterocyclyl group, as defined herein. Non-limiting heterocyclyl groups include pyrrolidinyl, piperidinyl, morpholinyl, oxazolyl, isoxazolyl, pyrrolyl, pyrazolyl, and the like.

As can be seen in formula (I) and (II), the SRP can be a poly(aldehyde), including poly(phthalaldehyde) or a generic poly(aldehyde) with a backbone consisting of alternating carbon and oxygen, including poly(oxymethylene). Such SRPs can be a linear or a cyclic homopolymer. The SRP can be a poly(phthalaldehyde) or a derivative thereof, such as a polymer including a structure of formula (Ia):

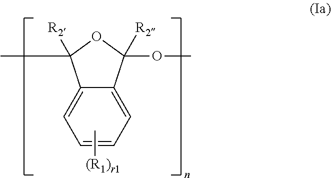

or a salt thereof, for any R₁, R_{2′}, R_{2″}, r1, and n described herein. In some instances, n is an integer from 4 to 100,000.

In other embodiments, the poly(phthalaldehyde) is cyclic. In some instances, the polymer has structure of formula (Ib) or (Ic):

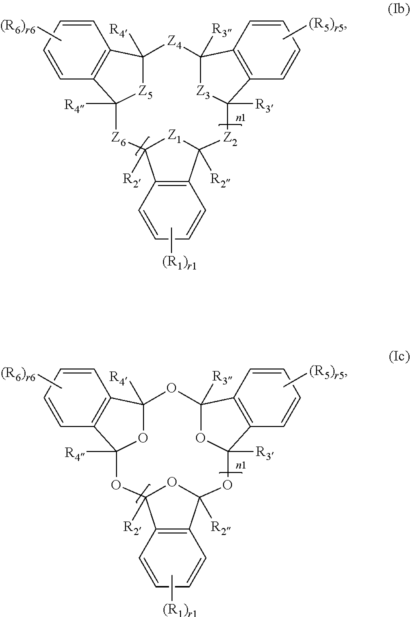

or a salt thereof, or any R₁, R₅, R₆, R_{2′}, R_{2″}, R_{3′}, R_{3″}, R_{4′}, R_{4″}, Z₁, Z₂, Z₃, Z₄, Z₅, Z₆, r1, r5, r6, and n1 described herein. In some instances, n1 is an integer from 1 to 100.

In any embodiment herein (e.g., in formula (I)-(VI) and (Ib)), each of Z₁ to Z₆, L₁, and L₂, if present, is, independently, an optionally substituted heteroalkylene selected from —CR₂R₃O—, —OCR₂R₃—, —OCR₂R₃O—, —(CR₂R₃S)ₕ₁CR₂R₃—, —S(CR₂R₃S)ₕ₁−, −CR₂R₃S—, —SCR₂R₃—, —SCR₂R₃S—, —(CR₂R₃S)ₕ₁CR₂R₃—, and —S(CR₂R₃S)ₕ₁—, in which each of R₂ and R₃ is, independently, H, optionally substituted alkyl, or optionally substituted aryl, and h1 is an integer from 1 to 5. In other embodiments, each of Z₁ to Z₆, L₁, and L₂, if present, is, independently, —O— or an optionally substituted heteroalkylene.

In any embodiment herein (e.g., in formula (I)-(V), (VII), and (XII)), each of R₂, R_{2′}, and R_{2″}, if present, is, independently, H or optionally substituted alkyl (e.g., C₁₋₆ alkyl).

In any embodiment herein (e.g., in formula (II), (III), (V), (VII), (IX), (X), (XI), and (XII)), R₃ is optionally substituted aryl.

In any embodiment herein (e.g., in formula (II), (III), (V), (VII), (IX), (X), (XI), and (XII)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)^{h1}R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

In any embodiment herein, the polymer is a homopolymer. Such a polymer can have any useful number n of monomers, such as n is from about 2 to about 100,000 (e.g., about 2 to 50, 2 to 100, 2 to 200, 2 to 300, 2 to 400, 2 to 500, 2 to 1,000, 2 to 2,000, 2 to 5,000, 2 to 10,000, 2 to 20,000, 2 to 50,000, 2 to 100,000, 3 to 50, 3 to 100, 3 to 200, 3 to 300, 3 to 400, 3 to 500, 3 to 1,000, 3 to 2,000, 3 to 5,000, 3 to 10,000, 3 to 20,000, 3 to 50,000, 3 to 100,000, 4 to 50, 4 to 100, 4 to 200, 4 to 300, 4 to 400, 4 to 500, 4 to 1,000, 4 to 2,000, 4 to 5,000, 4 to 10,000, 4 to 20,000, 4 to 50,000, 4 to 100,000, 5 to 50, 5 to 100, 5 to 200, 5 to 300, 5 to 400, 5 to 500, 5 to 1,000, 5 to 2,000, 5 to 5,000, 5 to 10,000, 5 to 20,000, 5 to 50,000, 5 to 100,000, 10 to 50, 10 to 100, 10 to 200, 10 to 300, 10 to 400, 10 to 500, 10 to 1,000, 10 to 2,000, 10 to 5,000, 10 to 10,000, 10 to 20,000, 10 to 50,000, 10 to 100,000, 50 to 100, 50 to 200, 50 to 300, 50 to 400, 50 to 500, 50 to 1,000, 50 to 2,000, 50 to 5,000, 50 to 10,000, 50 to 20,000, 50 to 50,000, 50 to 100,000, 100 to 200, 100 to 300, 100 to 400, 100 to 500, 100 to 1,000, 100 to 2,000, 100 to 5,000, 10 to 10,000, 100 to 20,000, 100 to 50,000, and 100 to 100,000). In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives. SRPs can include a copolymer including a structure of one of formulas (I)-(XIII), (Ia), (Ib), (Ic), or a salt thereof, as well as any copolymer described herein (e.g., one of formulas (XIV) or (XV)).

Further examples of SRPs are provided below. In some embodiments, the SRPs are copolymers including poly(aldehydes). In particular embodiments, they may be self-immolative polymers as described in U.S. Patent Publication No. 2018/0155483, which was published on Jun. 7, 2018, and which is hereby incorporated herein by reference in its entirety. Examples of copolymers in that reference include those of Formula (XIV):

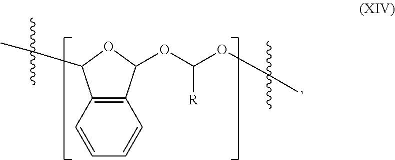

wherein:
R is substituted or unsubstituted C₁₋₂₀ alkyl, C₁₋₂₀ alkoxy, C₂₋₂₀ alkenyl, C₂₋₂₀ alkynyl, C₆₋₁₀ heteroaryl, C₃₋₁₀ cycloalkyl, C₃₋₁₀ cycloalkenyl, C₃₋₁₀ heterocycloalkyl, or C₃₋₁₀ heterocycloalkenyl; and, when substituted, R is substituted with C₁₋₂₀ alkyl, C₁₋₂₀ alkoxy, C₂₋₂₀ alkenyl, C₂₋₂₀ alkynyl, C₆₋₁₀ aryl, C₆₋₁₀ heteroaryl, carboxyaldehyde, amino, sulfonic acid, sulfinic acid, fluoroacid, phosphonic acid, ether, halo, hydroxyl, ketone, nitro, cyano, azido, silyl, sulfonyl, sulfinyl, or thiol.

In particular embodiments, the SRPs are cyclic copolymers of the phthalaldehyde monomer with a second aldehyde such as ethanal, propanal, or butanal. Examples of such copolymers are given in U.S. Patent Publication No. 2018/0155483 as Formula (XV):

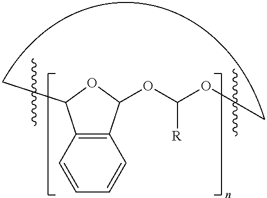

(XV), wherein n is an integer from 1 to 100,000 and R can be any described herein (e.g., such as for Formula (XIV)).

Specific examples in U.S. Patent Publication No. 2018/0155483 include copolymers of phthalaldehyde and one or more of acetaldehyde, propanal, butanal, pentanal, hexanal, heptanal, octanal, nonanal, decanal, undecanal, propenal, butenal, pentenal, hexenal, heptenal, octenal, nonenal, decenal, undecenal, and any combination thereof.

The SRPs may also be any appropriate linear or cyclic copolymer including the pure phthalaldehyde homopolymer. It also may be a homopolymer of poly(phthalaldehyde) derivatives such as poly(4,5-dichlorophthalaldehyde).

In other embodiments, the SRP is a homopolymer possessing a low MW, thereby providing a low viscosity polymer for filling gaps.

In any embodiment herein, the SRP can include a monomer that is or has a structure of any of formulas (I)-(XV), (Ia), or a salt thereof, in which n is 1, which is then linked to another monomer by way of a linker. Non-limiting linkers include optionally substituted alkylene, optionally substituted heteroalkylene, optionally substituted (aryl)(alkyl)ene, optionally substituted arylene, optionally substituted cycloalkylene, oxy, or thio. In other embodiments, the linker can be -Ak-, -Ak-X—, —X-Ak-, -(Ak-X)ₕ₁-Ak-, —X-(Ak-X)ₕ₁—, -Ak-Ar—, -Ak-Ar-Ak-, —Ar-Ak-, -(Ak-X)ₕ₁—Ar—, -(Ak-X)ₕ₁—Ar-(Ak-X)ₕ₁—, —Ar-(Ak-X)ₕ₁—, —X-(Ak-X)ₕ₁—Ar—, —X-(Ak-X)ₕ₁—Ar—X-(Ak-X)ₕ₁—, and —Ar—X-(Ak-X)ₕ₁—, in which Ak is an optionally substituted alkylene, Ar is an optionally substituted arylene, X is or includes a non-carbon heteroatom (e.g., —O—, —S—, or —NR^{N1}—, which R^{N1} is H, optionally alkyl, or optionally substituted aryl), and hl is an integer from 1 to 5.

In any embodiment herein, the SRP can be an amorphous polymer that remains solvent soluble.

The SRP can be synthesized using any corresponding monomer. For instance, the monomer can be or have a structure of any of formulas (I)-(XV), (Ia), or a salt thereof, in which n is 1. The monomer can have any useful end group disposed on either end of such a structure. In other embodiments, the monomer can be volatile and possess a melting point at or below 20° C.

In particular embodiments, the SRP is formed with no unwanted side products. In this way, residue-free vaporization of the polymer can be achieved because side products need not be removed. For removal, scission of one (or few) chemical bonds within the SRP propagates full, rapid depolymerization of the polymer. Since all the bonds are the same (no inadvertent impurities), little or no residue is expected.

The SRP, or a formulation thereof, can be deposited in any useful manner. For instance, the SRP can be spin-coated or vapor deposited.

In some embodiments, the SRP may include a metal binding moiety. This can be useful for certain applications.

### SRP Formulations

In some embodiments, an SRP that has a degradation temperature below its glass transition temperature (Tg) or melting temperature (Tm) may be used. Similarly, an SRP that has a degradation temperature above, but close to, a glass transition temperature or melting temperature may be used. For some SRPs, the degradation temperature is above or close to the Tg or Tm of the SRP. An SRP formulation may include a plasticizer to depress the Tg or Tm to a temperature sufficiently below the degradation temperature that a bake can be carried out without any degradation of the SRP.

Examples of plasticizers include phthalate esters such as dimethyl phthalate (DMP), diethyl phthalate (DEP), di-n-butyl phthalate (DBP), diisobutyl phthalate (DIBP), butyl benzyl phthalate (BBP), di-n-hexyl phthalate (DNHP), diisohexyl phthalate (DIHxP), diisononyl phthalate (DINP), diethylhexyl phthalate (DEHP), di(2-propylheptyl) phthalate (DPHP), di-n-octylphthalate (DOP), diisooctyl phthalate (DIOP), diisononyl phthalate, and diisodecyl phthalate (DIDP). In some embodiments, the plasticizer is a C3-C6 ortho-phthalate. Higher molecular weight phthalates may also be used.

In some embodiments, non-phthalate plasticizers may be used. Examples include aliphatic dibasic acid esters including glutarates (e.g., glycol ether glutarate), adipates (e.g., di-(2-ethylhexyl) adipate (DEHA), monomethyl adipate, dimethyl adipate, dioctyl adipate), azelates, and sebacates; benzoate esters (e.g, ethylene glycol) dibenzoate (DEGDB); trimellitates (e.g., trimethyl trimellitate, tri(2-ethylhexyl)trimellitate, tri(octyl,decyl)trimellitate, tri(heptyl,nonyl)trimellitate, and octyltrimellitate); polyesters; citrates; maleates (e.g., dibutyl maleate); glycols; polyethers; and phosphates.

The plasticizer may be provided in relatively small quantity. In some embodiments, it is provided in 1-35 pphr (parts per hundred resin) and may be 10 pphr or lower. As discussed below, a small amount of plasticizer is sufficient to depress the glass transition temperature. Larger quantities of plasticizer can result in phase separation or leave residues after SRP removal. The plasticizer should be soluble in the solvent used to spin coat the SRP solution.

Low ceiling temperature (Tc) polymers may have glass transition temperatures (Tg's) that are close to or above a degradation temperature and benefit from addition of a plasticizer in the formulation. Other SRPs including various polyglyoxylates, polyglyoxylamides, and polysulfones may be annealed without the addition of a plasticizer.

In some embodiments, the SRP is formulated with an organic weak acid. SRP films that include an organic weak acid are stable at room temperature but exhibit accelerated degradation characteristics compared to the neat SRP formulated without the organic weak acid. Organic weak acids are organic acids having a pKa≥1, with examples including tartaric acid and oxalic acid. Examples include linear alkyl carboxylic acids, C_{X}H_{2X}O₂, where X is an integer, and the corresponding dicarboxylic acid variants. Particular examples include including methanoic acid (X=1) and acetic acid (X=2). Particular examples of dicarboxylic acids include ethanedioic acid and propanedioic acid. The organic weak acid may also be variants of any of these with additional alcohol substitutions and/or unsaturated bonds. For example, oxoethanoic acid, 2-hydroxyethanoic acid, prop-2-enoic acid, 2-propynoic acid, 2-hydroxypropanedioic acid, oxopropanedioic acid, 2,2-dihydroxypropanedioic acid, 2-oxopropanoic acid, 2-hydroxypropanoic acid, 3-hydroxypropanoic acid, 2,3-dihydroxypropanoic acid, etc. may be used.

According to various embodiments, an SRP formulation may include a solvent, the SRP, a plasticizer, and, optionally, an organic weak acid. Example solvents include diglyme, N-methyl-pyrrolidone, dimethylformamide, tetrahydrofuran, propylene carbonate, cyclopentanone, anisole, dichlorobenzene, propylene glycol methyl ether acetate, and 2-ethoxyethyl acetate.

The formulation, and thus the resultant film, can include a photoacid generator (PAG), in which exposure of the SRP to electromagnetic radiation produces acid. In this way, energetic light (e.g., UV light, IR lights, or x-rays) exposure generates acid to promote in situ degradation of the film. Non-limiting photoacid generators include onium salts, such as iodonium and sulfonium salts having perfluorinated anions (e.g., diaryliodonium and triarylsulfonium salts), bissulfonyldiazomethane compounds, N-sulfonyloxydicarboximide compounds, and O-arylsulfonyloxime compounds. The photoacid generator may optionally include a photosensitizer (e.g., having modified polyaromatic hydrocarbons or fused aromatic rings).

Other acid generators can be used, such as a thermal acid generator that releases acidic moieties upon exposure to heat. In this way, depolymerization of the SRP can include both thermal and acidic processes. Non-limiting examples of thermal acid generators include ammonium salts, sulfonyl esters, and acid amplifiers. And as noted above, in some embodiments, the formulation may include a plasticizer.

### Vapor Deposition of SRPs

As described above, in some embodiments, vapor deposition of SRPs is employed. In some embodiments, vapor deposition of an SRP involves delivering an SRP precursor to a chamber housing the substrate on which the SRP is to be deposited.

Examples of SRP precursors include monomeric aldehydes and compounds having alternating carbon-oxygen ring structures. Examples of monomeric aldehydes include formaldehyde, ethanal, propanal, butanal, pentanal, hexanal, heptanal, octananal, nonanal, or decanal, or any non-linear branched version of these molecules. Examples of compounds with alternating carbon-oxygen ring structures that may be used as SRP precursors include 1,3,5-trioxane and paraldehyde.

In some examples, the precursors are combined over the substrate. For example, an energy source such as a heated wire filament or a hot surface are used to activate one or more of the precursors. In some examples, the substrate is cooled below a temperature of other surfaces in the processing chamber to promote adsorption of the precursors, or condensation of the polymer film, onto the substrate. In other examples, the substrate is heated to a predetermined temperature to promote the polymerization reaction.

The process is continued for a predetermined period until a predetermined thickness of the polymer film grows and then the reaction is stopped. In some examples, the predetermined thickness is in a range from 10 nm to 5000 nm. In some examples, the predetermined thickness is in a range from 50 nm to 5000 nm. In other examples, the predetermined thickness is in a range from 100 nm to 1000 nm.

In some examples, a chamber pressure during deposition of the polymer film is in a range from 50 mTorr to 100 Torr, or 50 mTorr to 10 Torr although other process pressures can be used. One or more precursor gases for the polymer film are supplied to the processing chamber. In some examples, two or more different precursors are used to make a copolymer film. In addition, initiators and/or catalysts can also be supplied, e.g., through a second plenum.

Incorporation of other components of an SRP formulation (e.g., an organic weak acid) may deposited at the same time as the polymer of the polymer film in some embodiments by flowing the weak acid or other component alongside the other precursors. In other embodiments, it may be added to the polymer film after deposition. For example, a deposited polymer film may be exposed to the vapor of the organic weak acid, and the organic weak acid diffuses into the film to some extent.

Referring to FIG. 1B, an example of a substrate processing module 110 for depositing the polymer film onto a substrate is shown. The substrate processing module 110 includes a processing chamber 122 that encloses other components of the substrate processing module 110. The substrate processing module 110 includes a gas distribution device 124 such as a showerhead that introduces and distributes process gases. Alternately, the process gases may be introduced in another manner. A substrate support 126 may be arranged below the gas distribution device 124. In some examples, the substrate support 126 includes a pedestal or an electrostatic chuck (ESC).

In some examples, the substrate support 126 is temperature controlled. In some examples, a temperature of the substrate support is used to help initiate polymer CVD. For example, the substrate support 126 may include resistive heaters 1and/or cooling channels 134. The cooling channels 134 may be supplied by fluid delivered using a pump 138 and a fluid source 140. One or more sensors 142 may be used to monitor a temperature of the substrate support 126. The one or more sensors 142 may include thermocouples that are located in the substrate support 126, or in fluid conduits connected to the substrate support 126. Alternately, other types of sensors such as thermal or infrared sensors located in the processing chamber 122 (remotely from the substrate support) can be used to monitor the temperature of the substrate or substrate support.

Surfaces of the processing chamber 122 can be heated by heaters 144. While the sidewalls of the processing chamber 122 are heated in FIG. 1B, other surfaces of the processing chamber 122 such as the top surface, the bottom surface and the gas distribution device can also be heated. In some examples, the surfaces of the processing chamber are heated to a temperature that is greater than a temperature of the substrate. One or more sensors 146 may be used to monitor chamber operating parameters such as temperature and/or pressure.

The substrate processing module 110 further includes a gas delivery system 150 with one or more gas sources 152-1, 152-2, . . . , and 152-N (collectively gas sources 152), where N is an integer greater than zero. The gas sources supply one or more gases to the processing chamber 122. The gas sources 152 are connected by valves 154-1, 154-2, . . . , and 154-N (collectively valves 154) and mass flow controllers (MFCs) 156-1, 156-2, . . . , and 156-N (collectively mass flow controllers 156) to a manifold 160. An output of the manifold 160 is fed to the processing chamber 122. For example only, the output of the manifold 160 is fed to the gas distribution device 124.

A vapor delivery system 170 may be used to deliver vaporized precursor to the processing chamber 122. The vapor delivery system 170 includes an ampoule 174 that stores liquid precursor 176. A heater 178 may be used to heat the liquid precursor as needed to increase vaporization. Pressure in the ampoule 174 may also be controlled to a predetermined pressure. Due to the monomer's instability when heated, the monomer may be kept at room temperature or even cooled, and a small portion that is delivered to a vaporizing device may be heated at point of vaporization

A valve system 180 may be used to control the supply of carrier or push gas from a gas source 182 and/or supply of the vaporized precursor. For example, the valve system 180 may include valves 184, 186 and 188. In this example, an inlet of the valve 184 is connected between the gas source 182 and an inlet of the valve 186. An outlet of the valve 184 is connected to an inlet of the ampoule 174. An outlet of the ampoule 174 is connected to an inlet of the valve 188. An outlet of the valve 188 is connected to an output of the valve 186 and to an inlet of the gas distribution device 124. The valve system 180 may be configured to supply no gas, carrier gas and/or carrier gas and vaporized precursor. A valve 190 and pump 192 may be used to control pressure in the processing chamber 122 and/or to evacuate reactants from the processing chamber 122.

A controller 198 may be used to control various components of the substrate processing module 110. For example only, the controller 198 may be used to control flow of process, carrier and precursor gases, vaporized precursor, water vapor, ammonia vapor, removal of reactants, monitoring of chamber parameters, etc. The controller 198 may be connected to or part of a larger system controller as discussed further below.

The substrate processing module 110 is an example of a module that may be part of a substrate processing system as described above with respect to FIG. 1A.

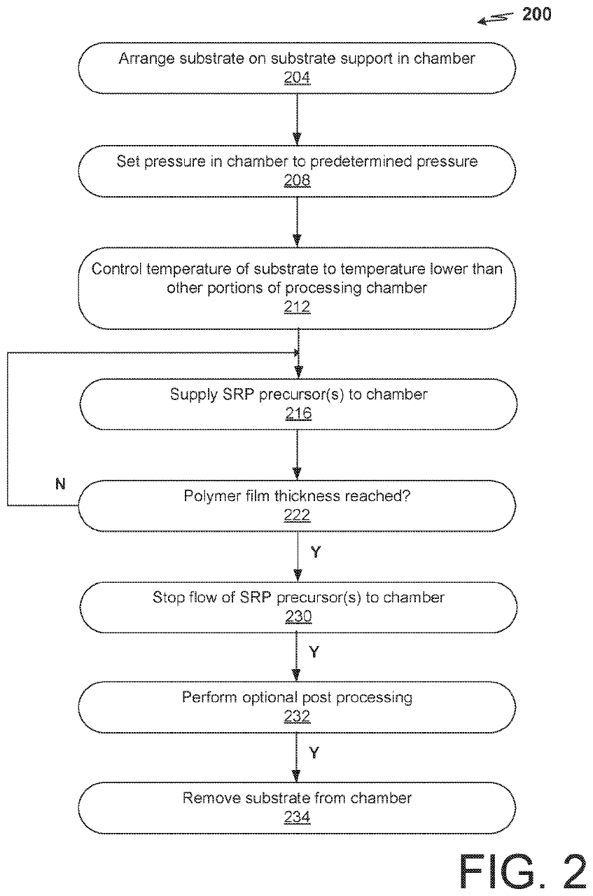

Referring now to FIG. 2, a method 200 for depositing an SRP film on a substrate is shown. At 204 in FIG. 2, the substrate is arranged on a substrate support in a chamber. At 208, the pressure in the chamber is set in a predetermined pressure range. At 212, the temperature of the substrate is controlled to a predetermined temperature range. In some examples, the temperature of the substrate is controlled to a temperature that is less than other surfaces in the chamber. At 216, a polymer precursor gas mixture is delivered to the chamber. Other gases, including an inert gas, a catalyst, or additive such as a weak organic acid may be delivered as well.

When a predetermined polymer film thickness is reached as determined at 222, the polymer precursor gas mixture is stopped at 230. At 232, optional post-processing is performed. In some examples, the post processing includes exposure to solvent, annealing and/or a soft-bake. The post processing can be performed in the same processing chamber where the film was grown, or the substrate can be moved to another processing chamber. For example, annealing may be used to improve film uniformity, to drive out unreacted precursors or other volatiles, to remove voids, or to improve film properties. At 234, the substrate is removed from the chamber.

In an example of vapor deposition of poly(oxymethylene), trioxane is delivered to a chamber at a flow rate of 10-10000 sccm and 50 mTorr to 50 Torr. Substrate temperature may be −10° C. to 80° C. An inert gas may be flowed at a flow rate 0-20000 sccm. A catalyst may be delivered to chamber, e.g., at flow rate of 10-10000 sccm. An example of a catalyst is boron trifluoride diethyl etherate (BF₃DEE). In some embodiments, a copolymer may be formed by adding a precursor such as octanal.

### SRP Removal

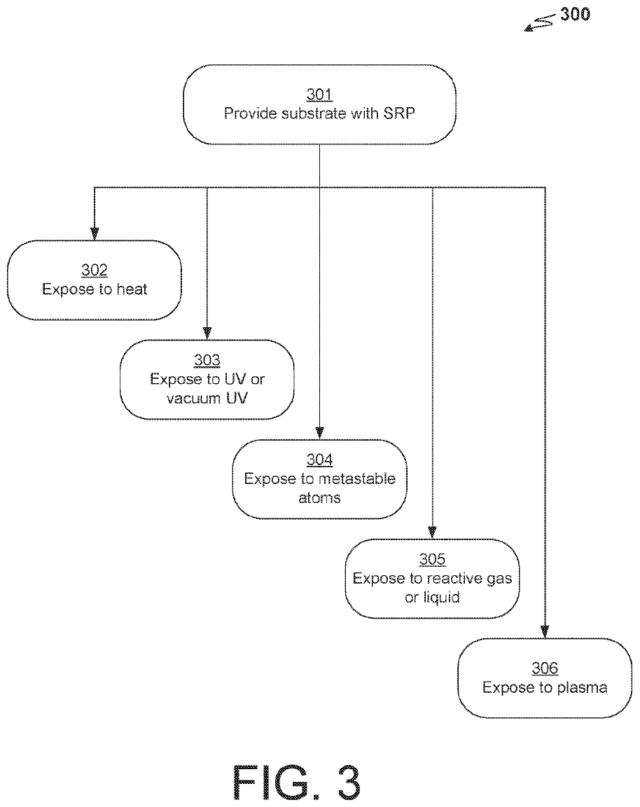

FIG. 3 is a flow diagram showing examples of operations for SRP removal according to various embodiments. A substrate is provided with SRP film in an operation 301. Operations 302-306 provide exposure to various types of stimuli, in which operations 302-306 may be used alone or in combination. In some embodiments, operation 301 involves providing the substrate to a processing chamber. In other embodiments, the substrate is in the chamber from a previous processing operation or is provided to a chamber in which a subsequent processing operation is to be performed. In some embodiments, the SRP is provided after a substantial queue time.

Within the chamber, the substrate can be exposed to heat in an operation 302. Heat can be provided as a constant temperature hold. Alternatively, heat can be provided as a ramped temperature, in which increasing or decreasing temperature ramping can be used between temperature holds. Such thermal energy can provide sufficient energy to depolymerize the SRP by providing heat at a temperature that is above the Tc. Such conditions can include exposure to a temperature of up to 400° C. for an SRP having a Tc that is below 400° C., in which the SRP is kinetically trapped below the Tc. In other embodiments, thermal exposure can include a temperature from about 50° C. to about 800° C. (e.g., about 50° C. to 150° C., 50° C. to 300° C., 50° C. to 500° C., 150° C. to 300° C., 150° C. to 400° C., 150° C. to 500° C., 200° C. to 400° C., 200° C. to 500° C., 200° C. to 600° C., 250° C. to 500° C., 250° C. to 600° C., 300° C. to 500° C., 300° C. to 550° C., 300° C. to 600° C., etc.). In particular embodiments, thermal exposure includes from about 300° C. to about 500° C. (e.g., for removing films including pure SRP). In other embodiments, thermal exposure includes exposure to an elevated temperature (e.g., up to 800° C.) with a fast ramp rate and a shorter time. When additives (e.g., a photoacid generator (PAG) or any herein) are used, the temperature for removal can be between about 50° C. and about 125° C., in addition to exposure to other stimulus that can beneficially activate the additive (e.g., UV exposure to activate the PAG).

For basic thermal removal of surface protection films (e.g., providing a substrate on a hot plate), exposure time can be from about 20 seconds to about 400 seconds (e.g., about 30 to 300 seconds). Thicker films can use longer exposure to heat for SRP removal, as compared to thinner films. Film thickness required will be application dependent. For instance, some removal thermal processes (e.g., using a rapid thermal processor (RTP)) can include higher temperatures (e.g., more than about 400° C.) for very short times (e.g., one to two seconds of exposure for RTP, as well as millisecond exposure times for flash lamp type processes). For applications that are thermal budget sensitive, RTP-type conditions can be employed, whereas other processes may employ a hot plate under vacuum.

Alternatively, the SRP can be removed by exposure to radiation (e.g., UV radiation or IR radiation), either with or without vacuum, in an operation 303. In some instances, process conditions include exposure to about 400° C. under vacuum at about 2.5 W/cm² UV dose rate. In other instances, process conditions (e.g., for an SRP employed with a photoacid generator) includes exposure to about 110° C. under vacuum for at about 0.05 mW/cm² UV dose rate. In any of these process conditions, exposure can include from about 100 seconds to about 400 seconds (e.g., about 300 seconds).

For radiation removal of surface protection films (e.g., pure SRP), exposure time can be from about 20 seconds to about 400 seconds (e.g., about 30 to 300 seconds). Thicker films can use longer exposure to radiation (e.g., UV) for SRP removal, as compared to thinner films. Film thickness required will be application dependent. For films with acid generating additives (e.g., PAG), the exposure times may range from two minutes to ten minutes. Exposure time can depend on many conditions, including the loading of the additives, wafer temperature, UV dose rate, and film thickness. These requirements, in turn, will be application dependent (e.g., depend on feature dimensions, aspect ratio, pattern density, etc.).

Radiation dosage can be, e.g., from about 0.1 mW/cm² to about 15 W/cm² for UV. For bracing applications in which rate control of the degradation can be desired, lower dose rates can be employed, e.g., from about 0.01 to about 0.07 mW/cm². For pure SRP film removal from blanket surfaces, higher dose rates can be employed, e.g., about 2.5 W/cm². Generally, the higher the dose rate, the cleaner the removal. Of course, radiation exposure can also be application dependent, and excessive radiation can be avoided to mitigate substrate damage.

During radiation exposure, the substrate can be maintained at an elevated temperature (e.g., from about 300° C. to about 500° C., including about 400° C.). When the formulation includes acid generating additives (e.g., PAG), then lower temperatures can be combined with UV exposure to provide a controlled degradation rate (e.g., temperature range of about 50° C. to about 125° C. or from about 100° C. to about 110° C.).

Metastable atoms are employed in another operation 304. The metastable atoms can be generated from a noble gas plasma, the noble gas being one or more of helium (He), neon (Ne), argon (Ar), krypton (Kr), and xenon (Xe), to remove residue from the substrate. In some embodiments, the metastable species are not chemically reactive and do not appreciably affect the underlying surface. The metastable species from the noble gas plasma can be effective at removing residues that remain after exposure to other stimuli such as heat.

In the methods described herein, removing SRPs includes exposure to high energy metastable species, generated in a noble gas plasma, at an elevated temperature. The metastable species have sufficient energies and lifetimes to scission bonds on the polymer or other residues. At temperatures greater than the ceiling temperature, there is a strong thermodynamic driving force to revert to volatile monomers once bond scissioning has occurred. The metastable species are not chemically reactive and do not appreciably affect the underlying surface. The metastable species are effective at removing residue that remains after exposure to other stimuli such as heat. This residue may be some SRP that remains polymerized or cross-linked and/or carbonized shards that is detectable by ellipsometry. While most of the SRP can be removed by the stimuli described above, this residue can be difficult to fully remove by those methods. Without being bound by a particular theory, the metastables may remove residues by re-initiating chain scissioning that may have stopped prematurely due to side product formation, by breaking down char that may have formed during the depolymerization process, and by aiding monomer desorption.

In some embodiments, most of the SRP is removed before exposing the substrate to the metastable atoms. In some embodiments, the substrate is exposed to the metastable atoms before most of the SRP is removed. In some embodiments, the plasma pressure is between about 10 mTorr to 10 Torr. In some embodiments, the plasma pressure is between about 100 mTorr and 1 Torr. In some embodiments, the SRP is provided between HAR structures. In some embodiments, the SRP is provided as a protective coating on substrate. In some embodiments, the plasma is generated in an inductively coupled plasma (ICP) source. In some such embodiments, the ICP source is separated from the substrate by a showerhead or other filter. In some embodiments, the plasma is generated in capacitively coupled plasma (CCP) source. Any other type of plasma source may be used. In some embodiments, exposing the substrate to a stimulus and exposing the substrate to the metastable atoms are performed in the same chamber

Processing and plasma source chamber pressure may be used to control the plasma-based removal. Pressure is important to control the density of the metastable atoms. If pressure is too low, the density of metastable atoms may not be high enough to efficiently clean the surface. If the pressure is too high, metastable species may be lost to collisions. Example pressures may range from 10 mTorr to 10 Torr, 100 mTorr to 1 Torr, 100 mTorr to 700 mTorr, 200 mTorr to 1 Torr, or 200 mTorr to 2 Torr.

Substrate temperature and plasma power may also be used to control removal. Temperature is high enough such that it is above the ceiling temperature of the polymer. Higher temperatures aid removal with the maximum temperature limited by the thermal budget of the device or other materials on the substrate. Example temperatures may range from 150° C. to 1000° C. or from 150° C. to 400° C. Plasma power is high enough to generate metastable atoms. Example powers may range from 500 W to 5000 W or from 800 W to 5000 W, e.g., 2500 W for a 300 mm wafer, and scale linearly with substrate area. Example exposure times may range from 10 seconds to 300 seconds or from 10 seconds to 180 seconds.

As seen in FIG. 3, yet other conditions include exposure to reactive gas or liquid (e.g., acidic or basic vapors or liquid) in an operation 305 or exposure to plasma in an operation 306. Examples of reactive gas for example include oxygen (O₂), hydrogen bromide (HBr), hydrogen chloride (HCl), hydrogen fluoride (HF), and hydrogen sulfide (H₂S).

In some embodiments, an acid (e.g., having a pKa of less than 7, and in some embodiments less than 4, or less than 2) or a base (e.g., having a pKb of less than 7, and in some embodiments, less than 4 or less than 2) is provided. Non-limiting reactants include sulfurous acid, nitric acid, carbonic acid, or ammonium hydroxide.

A catalyst can be used with the acid, base, or a reactant that forms the acid or base. Non-limiting catalysts include hydrogen bromide (HBr), hydrogen chloride (HCl), hydrogen fluoride (HF), hydrogen iodide (HI), nitric acid (HNO₃), formic acid (CH₂O₂), acetic acid (CH₃COOH), formonitrile (HCN), sulfurous acid (H₂SO₃), carbonic acid (H₂CO₃), nitrous acid (HNO₂), or ammonia (NH₃), and methyl or ethyl amine gas or vapor may be used. In some examples, when HBr vapor is used, the substrate is maintained at a pressure in a range from 1 mTorr to 5000 mTorr (e.g., from 5 mTorr to 5000 mTorr) and a temperature in a range from 0° C. to 200° C. (e.g., from 0° C. to 100° C.). In some examples, the substrate is maintained at a pressure in a range from 750 mTorr to 1500 mTorr and a temperature in a range from 35° C. to 70° C. In some examples, the temperature of the substrate is maintained at a pressure of 1000 mTorr and a temperature of 60° C. The amount of acidic vapor or vapor of other compound is controlled to limit the diffusion. Exposure time can depend on the strength of the acid or base, as well as film thickness and exposure temperature (e.g., from about 20° C. to about 125° C. or from about 100° C. to about 125° C.). Non-limiting exposure time can include less than about 60 seconds or on the order of minutes.

Removal can occur in a single step or in a plurality of steps. For example, a stimulus that degrades SRP may be pulsed in the chamber in an operation. Such stimulus can include exposure to a compound (e.g., an acid, a base, a compound that forms an acid or base, plasma, metastable compounds, etc.) or a reaction condition (e.g., UV radiation, IR radiation, heat, etc.). In some embodiments, removal includes exposure to heat and/or radiation, thus eliminating the need for plasma and/or harsh wet chemistries that will modify the sensitive surfaces that need to be protected. When a compound is used, the partial pressure of the vapor and/or the pulse time can be controlled to control the overall exposure to the vapor and the diffusion depth. The chamber can be purged between pulses. Purging can involve evacuating the chamber and/or flowing inert gas to be swept out through the chamber. Such a gas may be, for example, continuously flowing including during the operation or may be itself pulsed into the chamber. Volatilized monomer or SRP fragment may be pumped or purged out of the chamber.

In other embodiments, removal can include exposure to two reactants that react to form an acid or base that can trigger the degradation of the SRP. The exposure occurs sequentially to provide more precise top-down control. In some embodiments, the methods involve diffusing a compound, or a reactant that reacts to form a compound, only to a top portion of the SRP. The top portion is then degraded and removed, leaving the remaining SRP intact. The exposure and removal cycles can be repeated. Optionally, a purge operation can follow the exposure operation to remove the compound or reactant from the chamber.

Non-limiting reactants (e.g., to form an acid or base) can include water vapor with one of ammonia (NH₃) or a gaseous oxide, which reacts with the water vapor to an acidic or basic species. For instance, NH₃ and water can react to form ammonium hydroxide (NH₄OH). Examples of gaseous oxides include nitrogen dioxide (NO₂, which can react with water to form nitric acid, HNO₃), sulfur dioxide (SO₂, which can react with water to form sulfurous acid, H₂SO₃), and carbon dioxide (CO₂, which can react with water to form carbonic acid, H₂CO₃). Other oxides may react with water or another reactant to form acids or bases.

According to various embodiments, the reaction may be catalyzed or uncatalyzed. In some embodiments, a catalyst (e.g., a thermally activated catalyst) may be provided in the SRP, delivered with a reactant, or introduced as a separate pulse. However, in many embodiments, the reaction is uncatalyzed such that SRP is provided free of catalysts. This can facilitate SRP removal. In some embodiments, the reaction is byproduct-free. In some embodiments, thermal removal in vacuum is used with temperature below the thermal budget for the structure.

### Pre-Capping and Post-Capping Substrate Processes and Modules

As described above, substrate processing is performed prior to a sacrificial capping layer is deposited on a sensitive surface and after the sacrificial capping layer is removed from the sensitive surface. Below are examples of substrate processes that may be performed before sacrificial capping layer deposition and/or after sacrificial capping layer deposition.

In some embodiments, a sensitive surface of a substrate on which a capping layer is formed includes a thin metal film. In some embodiments, the thin metal film is deposited on a substrate followed by deposition of the sacrificial capping layer. Metals that may be deposited include cobalt, vanadium, niobium, tantalum, chromium, tungsten, iron, ruthenium, nickel, zinc, copper, and molybdenum. Examples of applications include middle-of-line (MOL) or back end of line (BEOL) interconnects. In one example, the methods may be used for source/drain contact fill. The substrate may be provided to a semiconductor processing module as described above with respect to FIG. 1A. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. The feature(s) may be formed in one or more of the above-described layers. One example of a feature is a pillar or pole in a semiconductor substrate or a layer on the substrate. Another example is a trench in a substrate or layer.

In some embodiments, the feature(s) such as a pillar may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 10 nm and about 100 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

The feature may be a trench or via that is formed in a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low K dielectrics, such as carbon-doped SiO₂. The metal may be deposited in the feature to make electrical contact to an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and titanium (Ti). Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPtySix). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewall surfaces and a bottom surface. In some embodiments, the sidewall surfaces may be the same material as the bottom surface. For example, in some embodiments, the sidewall surfaces and the bottom surface are titanium nitride (TiN), tungsten carbon nitride (WCN) or tantalum nitride (TaN). In some embodiments, the sidewall surfaces may be a different material than the material of the bottom surface. For example, the bottom surface may be a metal or metal silicide and the sidewall surface may be a silicon oxide, such as SiO₂.

Atomic layer deposition (ALD) is a technique that deposits thin layers of material using sequential self-limiting reactions. ALD processes use surface-mediated deposition reactions to deposit films on a layer by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of metal films, this reaction involves reacting oxygen plasma with carbon and nitrogen to form a gaseous species; oxidizing metal to metal oxide; eliminating trace carbon, nitrogen, and hydrogen impurities; and increasing bonding and densification of the film.

Unlike a chemical vapor deposition (CVD) technique, ALD processes use surface mediated deposition reactions to deposit films on a layer-by-layer basis. In one example of an ALD process, a substrate surface that includes a population of surface-active sites is exposed to a gas phase distribution of a first precursor, such as a metal-containing precursor, in a dose provided to a chamber housing a substrate. Molecules of this first precursor are adsorbed onto the substrate surface. It should be understood that when a compound is adsorbed onto the substrate surface as described herein, the adsorbed layer may include the compound as well as derivatives of the compound. For example, an adsorbed layer of a metal-containing precursor may include the metal-containing precursor as well as derivatives of the metal-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

The metal may be deposited by a plasma enhanced atomic layer deposition (PEALD) method. PEALD is a surface-mediated deposition technique in which doses of a precursor and a reactant (a reducing gas in plasma form) are sequentially introduced into a deposition chamber. In some embodiments, the gas is pure hydrogen, hydrogen mixed with inert argon or helium. In some embodiments, small amounts of oxygen may also be added. Total flow rate will depend upon chamber geometry and size. The amount of hydrogen may range from about 100% when pure hydrogen is utilized to about 5% hydrogen when mixed with an inert gas. For PEALD, the temperature of the substrate and the pressure of a chamber may be controlled. In some embodiments, the substrate may be heated to a temperature of about 300° C. or lower, e.g., about 300° C. to about 50° C. In some embodiments, the chamber may be pressurized to less than about 10 Torr. In some embodiments, the chamber pressure may be in the range of from about 0.1 to about 9.9 Torr. In some embodiments, the duration of exposure is from about 5 or 10 seconds to about 2 minutes.

To deposit a metal thin film, a substrate surface is exposed to a metal precursor. In some embodiments, the metal precursors may be molybdenum precursors, copper precursors, tungsten precursors, cobalt precursors, or ruthenium precursors among others. Examples of metal precursors are provided in U.S. Patent Provisional Application No. 63/366,888, filed Jun. 23, 2022, and incorporated by reference herein.

The deposition chamber is optionally purged after introduction of the metal precursor. Then, in some embodiments, surface of the substrate is exposed to a plasma of a hydrogen-containing gas source (the reactant).

Direct plasma conditions sometimes employed in PEALD can lead to directionality in the deposition because the energy to break up the precursor molecules can be a low frequency which creates a lot of ion bombardment at the surface. The directional deposition can also lead to deposition of films with poor step coverage. A direct plasma is a plasma in which the plasma (electrons, neutral species, radicals, and positive ions at an appropriate concentration) resides in close proximity to the substrate surface during deposition, sometimes separated from the substrate surface by only a plasma sheath. In some embodiments, the plasma is generated remotely.

In some embodiments, a plasma of reactive species is formed. The plasma species could include electrons, positive ions, neutral species, radicals, and other plasma species. In some embodiments, the plasma may be a hydrogen-based plasma as the hydrogen-containing source including hydrogen atoms, hydrogen radicals, hydrogen reactive species, hydrogen plasma or combinations thereof. The plasma may be an oxygen-based plasma as the oxygen-containing source including oxygen atoms, oxygen radicals, oxygen reactive species, oxygen plasma or combinations thereof. In some embodiments, the plasma may also comprise noble gas species, for example argon, neon, krypton, xenon, or helium species. In some instances, the plasma may comprise other species, for example, nitrogen atoms, nitrogen radicals, nitrogen plasma or combinations thereof.

In some embodiments the substrate is contacted with a reactant comprising hydrogen, oxygen, and helium plasma. The plasma may be formed in a reaction chamber or upstream of a reaction chamber, for example by flowing the hydrogen, oxygen, and helium through a remote plasma generator, thereby generating plasma species that are introduced downstream to the reaction chamber. Alternatively, hydrogen and helium plasma may be fed into a reaction chamber separately from oxygen and helium plasma. In some embodiments, the hydrogen gas is supplied in a volume of from about 500 to about 5000 sccm (standard cubic centimeters/minute/one station chamber). In some embodiments of the plasma pre-treatment, the oxygen gas is supplied in a volume of from about 1 to about 150 sccm. In some embodiments, the oxygen gas is supplied in a volume of from about 15 to about 100 sccm. In some embodiments of the plasma pre-treatment, the helium gas is supplied in a volume of from about 1000 to about 10,000 sccm. In some embodiments, helium may be omitted. In some embodiments, another inert gas may be used instead of or in addition to helium.

If the desired thickness is achieved, the process can be ended. The desired thickness may range from about less than 1 nm to about 50 nm, depending upon the application. If the desired thickness has not yet been achieved, the process can be repeat for the number of cycles sufficient to achieve the desired metal thickness.

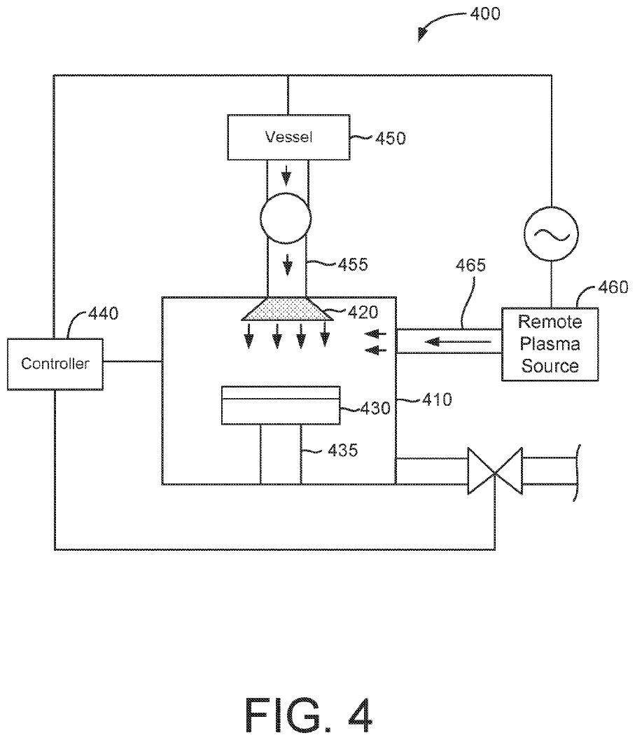

FIG. 4 presents a schematic diagram of a remote plasma processing module according to certain embodiments that may be used for ALD deposition. The module 400 includes a reaction chamber 410 with a showerhead assembly 420. Inside the reaction chamber 410, a substrate 430 rests on a stage or pedestal 435. In some embodiments, the pedestal 435 can be fitted with a heating/cooling element. A controller 440 may be connected to the components of the processing module 400 to control the operation of the processing module 400. For example, the controller 440 may contain instructions for controlling process conditions for the operations of the processing module 400, such as the temperature process conditions and/or the pressure process conditions. In some embodiments, the controller 440 may contain instructions for controlling the flow rates of precursor gas, co-reactant gas, source gas, and carrier gas. The controller 440 may contain instructions for changing the flow rate of the co-reactant gas over time. In addition, or in the alternative, the controller 440 may contain instructions for changing the flow rate of the precursor gas over time. The controller 440 may be connected to or part of a larger system controller as discussed further below.

During operation, gases or gas mixtures are introduced into the reaction chamber 410 via one or more gas inlets coupled to the reaction chamber 410. In some embodiments, two or more gas inlets are coupled to the reaction chamber 410. A first gas inlet 455 can be coupled to the reaction chamber 410 and connected to a vessel 450, and a second gas inlet 465 can be coupled to the reaction chamber 410 and connected to a remote plasma source 460. In embodiments including remote plasma configurations, the delivery lines for the precursors and the radical species generated in the remote plasma source are separated. Hence, the precursors and the radical species do not substantially interact before reaching the substrate 430.

One or more radical species may be generated in the remote plasma source 460 and configured to enter the reaction chamber 410 via the gas inlet 465. Any type of plasma source may be used in remote plasma source 460 to create the radical species. This includes, but is not limited to, capacitively coupled plasmas, inductively coupled plasmas, microwave plasmas, DC plasmas, and laser-created plasmas. An example of a capacitively coupled plasma can be a radio frequency (RF) plasma. A high-frequency plasma can be configured to operate at 13.56 MHz or higher. Another example of such a RF remote plasma source 460 may be one which can be operated at 440 kHz and can be provided as a subunit bolted onto a larger apparatus for processing one or more substrates in parallel. In some embodiments, a microwave plasma can be used as the remote plasma source 460. A microwave plasma can be configured to operate at a frequency of 2.45 GHz. Gas provided to the remote plasma source may include hydrogen, nitrogen, oxygen, and other gases as mentioned elsewhere herein. In certain embodiments, hydrogen is provided in a carrier such helium. As an example, hydrogen gas may be provided in a helium carrier at a concentration of about 1-10% hydrogen.

The precursors can be provided in vessel 450 and can be supplied to the showerhead 420 via the first gas inlet 455. The showerhead 420 distributes the precursors into the reaction chamber 410 toward the substrate 430. The substrate4 can be located beneath the showerhead 420. It will be appreciated that the showerhead 420 can have any suitable shape and may have any number and arrangement of ports for distributing gases to the substrate 430. The precursors can be supplied to the showerhead 420 and ultimately to the substrate 430 at a controlled flow rate.

The one or more radical species formed in the remote plasma source 460 can be carried in the gas phase toward the substrate4. The one or more radical species can flow through a second gas inlet 465 into the reaction chamber 410. It will be understood that the second gas inlet 465 need not be transverse to the surface of the substrate 430. In certain embodiments, the second gas inlet 465 can be directly above the substrate 430 or in other locations. The distance between the remote plasma source 460 and the reaction chamber 410 can be configured to provide mild reactive conditions such that the ionized species generated in the remote plasma source 460 are substantially neutralized, but at least some radical species in substantially low energy states remain in the environment adjacent to the substrate 430. Such low energy state radical species are not recombined to form stable compounds. The distance between the remote plasma source 460 and the reaction chamber 410 can be a function of the aggressiveness of the plasma (e.g., determined in part by the source RF power level), the density of gas in the plasma (e.g., if there's a high concentration of hydrogen atoms, a significant fraction of them may recombine to form H₂ before reaching the reaction chamber 410), and other factors. In some embodiments, the distance between the remote plasma source 460 and the reaction chamber 410 can be between about 1 cm and 30 cm, such as about 5 cm or about 15 cm.

In some embodiments, a co-reactant, which is not the primary metal-containing precursor or a hydrogen radical, is introduced during the deposition reaction. In some implementations, the apparatus is configured to introduce the co-reactant through the second gas inlet 465, in which case the co-reactant is at least partially converted to plasma. In some implementations, the apparatus is configured to introduce the co-reactant through the showerhead 420 via the first gas inlet 455. Examples of the co-reactant include oxygen, nitrogen, ammonia, carbon dioxide, carbon monoxide, and the like. The flow rate of the co-reactant can vary over time to produce a composition gradient in a graded film.

The substrate processing module 400 is an example of a module that may be part of a substrate processing system as described above with respect to FIG. 1A. In some embodiments, for example, a thin metal film may be deposited on a substrate as described above in a substrate processing module 400. The substrate may then be transferred to module as depicted in FIG. 1B for deposition of a capping layer prior to leaving the vacuum environment.

Removal of a capping layer from a metal thin film can depend on the thermal budget of the metal thin film and/or underlying layers. For example, for back end of line (BEOL) processes, a thermal budget may be 300° C. to 400° C. In a specific example, the thermal budget of a cobalt (Co) thin film may be between 200° C. and 300° C.

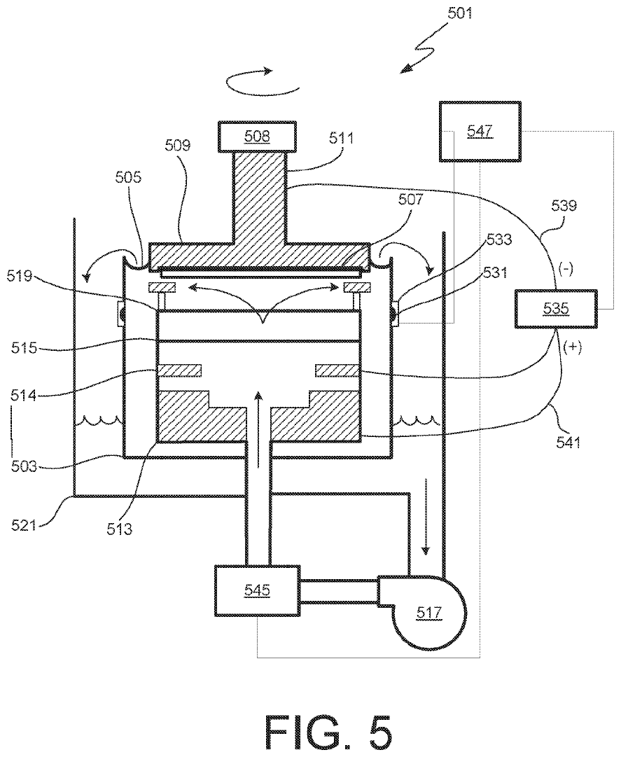

FIG. 5 shows an example of an electroplating cell that may be used for pre-or post-processing. For example, in some embodiments, the sensitive surface of a substrate includes a metal feature formed using an electroplating apparatus. Often, an electroplating apparatus includes one or more electroplating cells in which the substrates (e.g., wafers) are processed. Only one electroplating cell is shown in FIG. 5 to preserve clarity. To optimize bottom-up electroplating, additives (e.g., accelerators, suppressors, and levelers) are added to the electrolyte; however, an electrolyte with additives may react with the anode in undesirable ways. Therefore anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 5, a diagrammatical cross-sectional view of an electroplating apparatus 501 in accordance with one embodiment is shown. The plating bath 503 contains the plating solution (having a composition as provided herein), which is shown at a level 505. The catholyte portion of this vessel is adapted for receiving substrates in a catholyte. A wafer 507 is immersed into the plating solution and is held by, e.g., a “clamshell” substrate holder 509, mounted on a rotatable spindle 511, which allows rotation of clamshell substrate holder 509 together with the wafer 507.

An anode 513 is disposed below the wafer within the plating bath 503 and is separated from the wafer region by a membrane 515, preferably an ion selective membrane. For example, Nafion™ cationic exchange membrane (CEM) may be used. The region below the anodic membrane is often referred to as an “anode chamber.” The ion-selective anode membrane 515 allows ionic communication between the anodic and cathodic regions of the plating cell, while preventing the particles generated at the anode from entering the proximity of the wafer and contaminating it. The anode membrane is also useful in redistributing current flow during the plating process and thereby improving the plating uniformity. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating, the ions from the plating solution are deposited on the substrate. The metal ions must diffuse through the diffusion boundary layer and into the through silicon via (TSV) hole, opening, or other feature. A typical way to assist the diffusion is through convection flow of the electroplating solution provided by the pump 517. Additionally, a vibration agitation or sonic agitation member may be used as well as wafer rotation. For example, a vibration transducer 508 may be attached to the clamshell substrate holder 509.

The plating solution is continuously provided to plating bath 503 by the pump 517. Generally, the plating solution flows upwards through an anode membrane 515 and a diffuser plate 519 to the center of wafer 507 and then radially outward and across wafer 507. The plating solution also may be provided into the anodic region of the bath from the side of the plating bath 503. The plating solution then overflows the plating bath 503 to an overflow reservoir 521. The plating solution is then filtered (not shown) and returned to pump 517 completing the recirculation of the plating solution. In certain configurations of the plating cell, a distinct electrolyte is circulated through the portion of the plating cell in which the anode is contained, while mixing with the main plating solution is prevented using sparingly permeable membranes or ion selective membranes.

A reference electrode 531 is located on the outside of the plating bath 503 in a separate chamber 533, which chamber is replenished by overflow from the main plating bath 503. Alternatively, in some embodiments the reference electrode is positioned as close to the substrate surface as possible, and the reference electrode chamber is connected via a capillary tube or by another method, to the side of the wafer substrate or directly under the wafer substrate. In some of the preferred embodiments, the apparatus further includes contact sense leads that connect to the wafer periphery and which are configured to sense the potential of the metal seed layer at the periphery of the wafer but do not carry any current to the wafer.

A reference electrode 531 is typically employed when electroplating at a controlled potential is desired. The reference electrode 531 may be one of a variety of commonly used types such as mercury/mercury sulfate, silver chloride, saturated calomel, or copper metal. A contact sense lead in direct contact with the wafer 507 may be used in some embodiments, in addition to the reference electrode, for more accurate potential measurement (not shown).

A DC power supply 535 can be used to control current flow to the wafer 507. The power supply 535 has a negative output lead 539 electrically connected to wafer 507 through one or more slip rings, brushes, and contacts (not shown). The positive output lead 541 of power supply 535 is electrically connected to an anode 513 located in plating bath 503. The power supply 535, a reference electrode 531, and a contact sense lead (not shown) can be connected to a system controller 547, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 535 biases the wafer 507 to have a negative potential relative to anode 513. This causes an electrical current to flow from anode 513 to the wafer 507, and an electrochemical reduction (e.g. Cu²⁺2e⁻=Cu⁰) occurs on the wafer surface (the cathode), which results in the deposition of the electrically conductive layer (e.g., copper) on the surfaces of the wafer. An inert anode 514 may be installed below the wafer 507 within the plating bath 503 and separated from the wafer region by the membrane 515.

The apparatus may also include a heater 545 for maintaining the temperature of the plating solution at a specific level. The plating solution may be used to transfer the heat to the other elements of the plating bath. For example, when a wafer 507 is loaded into the plating bath, the heater 545 and the pump 517 may be turned on to circulate the plating solution through the electroplating apparatus 501, until the temperature throughout the apparatus becomes substantially uniform. In one embodiment, the heater is connected to the system controller 547. The system controller 547 may be connected to a thermocouple to receive feedback of the plating solution temperature within the electroplating apparatus and determine the need for additional heating.

The apparatus 501 is an example of a module that may be part of a substrate processing system as described above with respect to FIG. 1A. In some embodiments, for example, a substrate processing apparatus 102b as shown in FIG. 1A may be or include an electroplating apparatus. A substrate having a capping layer deposited thereon may be transferred to the apparatus 501.

To remove a capping layer in an electroplating apparatus, in some embodiments, a substrate is exposed to radiation after it is transferred to the apparatus and prior to being immersed in the plating bath. The apparatus 501 may include a laser source, an infrared source, or other radiation source positioned at the top of the apparatus to directed targeted pulses. The capping layer is thermally desorbed into gas prior to being clamped and lowered into the plating bath. In such cases, the apparatus 501 may be oxygen-free or purged to avoid oxygen exposure after the capping layer is removed. For example, nitrogen or forming gas may be used to positively displace all oxygen in the apparatus.

In some embodiments, a capping layer that can be chemically removed is used and the film is removed in the plating bath prior to plating. Examples include a hermetic oxide that is removed by the acid in the plating bath and a water soluble polymer removed by water in the plating bath. In such embodiments, the substrate may be exposed to oxygen prior to immersion in the plating bath as the capping layer is present to protect it.

In some embodiments, the composition of the liquid during the removal operation is different from that during subsequent plating. Any capping layer that is acid-, base-, or water-soluble may be used. Examples include carbides and nitrides that are acid-soluble and/or base-soluble. In such embodiments, the immersion liquid may be changed from removal to plating compositions in-situ though the addition of concentrates or full replacement to avoid oxygen exposure after capping layer removal.

As indicated above, in some embodiments, the capping layer is an oxide that may be removed. In some embodiments, it may be an oxide of the underlying metal. For example, a layer of cobalt oxide may be used to cap a cobalt layer. In such cases, the capping layer is a deposited cobalt oxide layer, thicker, denser, or otherwise more uniformly resistant to subsequent oxidation than a native oxide layer that may otherwise form on a cobalt layer exposed to atmosphere. For example, a 2 nm oxide, or an oxide densified with plasma treatment, or an amorphous oxide not susceptible to preferential grain boundary oxygen penetration might be used. In another example, alumina may be deposited over a seed layer that and removed in an acid or base.

Deposition of sacrificial capping layers for seed layers, including oxides and nitrides, is described further below.

As indicated above, a bath composition may be modified. For example, a high acid and/or high base bath may be used for removal, with the acid or base content lowered for plating. In some embodiments, mass transport conditions suited for dissolution of the capping layer may be used for removal and changed for plating. Rotation rate of the substrate in the bath and/or flow rate of the liquid can be high for removal and lowered for electrodeposition. In an example, the substrate may be rotated at 100 rpm with flow rate of 18 liters per minute (lpm) for removal and lowered to 30 rpm and 6 lpm.

As indicated above, any suitable deposition apparatus appropriate for performing the metal seed deposition operations may be used, including PVD apparatuses that use hollow cathode magnetron (HCM) or planar magnetron targets.

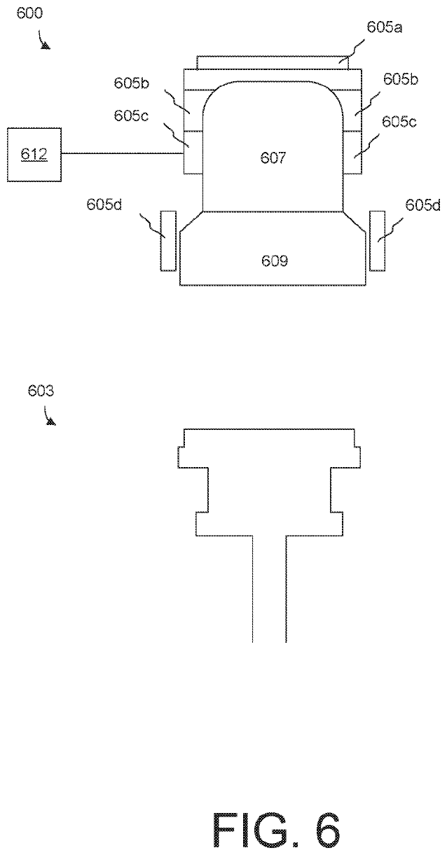

FIG. 6 shows an example of a physical vapor deposition (PVD) module 600 that may be used for pre-or post-processing. Examples of PVD modules include apparatuses that use hollow cathode magnetron (HCM) or planar magnetron targets. FIG. 6 presents a simple cross-sectional view of one type of HCM sputtering apparatus. The PVD module 600 has two main components, the source 601, in which plasma is created and maintained, and the RF bias electrostatic chuck (ESC) pedestal 603, which secures the wafer and applies an RF bias on the wafer, if needed. In this specific example, the source 601 contains four electromagnets 605a-605d, a cathode target 607 and an anode 609. The cathode target 607 generally has a hollow cup-like shape so that plasma formed in the source can be concentrated within this hollow region. The cathode target 607 also serves as a sputter target and is, therefore, made of the metal material, such as copper or copper alloy, which is to be deposited onto the substrate.

An inert gas, such as argon, is introduced to into the hollow region of the cathode target 607 to form plasma. An intense magnetic field is produced by electromagnets 605a-605d within the cathode target region. Additional electromagnets are arranged downstream of the cathode target so that different currents can be applied to each electromagnet, thereby producing an ion flux and a controlled deposition and/or etch rate and uniformity. A metal spacer 609, typically held at plasma floating potential, is used, in conjunction with the source electromagnets to shape the plasma distribution at the target mouth. The RF bias ESC pedestal 603 holds the wafer substrate in place and can apply a RF bias to the wafer substrate. The ion energy, and therefore the deposition and/or etch rate can also be controlled by the pedestal RF bias. Typically, the amount of sputtering is controlled by the RF power at fixed RF frequency. Various RF frequencies can be used to achieve this effect, for example, 13.56 MHz. An additional function of the ESC pedestal is to provide wafer temperature control during sputter etch and deposition. Typically, argon backside gas is used to provide thermal coupling between the substrate and the ESC. In many cases, the ESC is cooled during deposition.

The PVD module 600 is an example of a module that may be part of a substrate processing system as described above with respect to FIG. 1A. In some embodiments, for example, a capping layer may be removed in a module 105b. The substrate may then be transferred to a PVD module 107b as depicted in FIG. 1A for a PVD deposition and/or reflow operation.

In the examples above, a controller is described to control process conditions and operations. The controller will typically include one or more memory devices and one or more processors. A processor may include a CPU or computer, analog and/or digital input/output connections, stepper motor controller boards, etc.

The controller may control all the activities of a removal apparatus. The system controller executes system control software, including sets of instructions for controlling the timing, mixture of gases, chamber pressure, chamber temperature, wafer temperature, wafer chuck or pedestal position, plasma power, and other parameters of a particular process. Other computer programs stored on memory devices associated with the controller may be employed in some embodiments.

Typically, there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the reactant pulses and purge gas flows and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, substrate temperature, and plasma power. These parameters are provided to the user in the form of a recipe and may be entered utilizing the user interface.

Signals for monitoring the process may be provided by analog and/or digital input connections of the system controller. The signals for controlling the process are output on the analog and digital output connections of the system.

The system software may be designed or configured in many ways. For example, various module component subroutines or control objects may be written to control operation of the module components necessary to carry out the processes in accordance with the disclosed embodiments. Examples of programs or sections of programs for this purpose include substrate positioning code, process gas control code, pressure control code, plasma power code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

### Sacrificial Capping Layer for Seed Layer

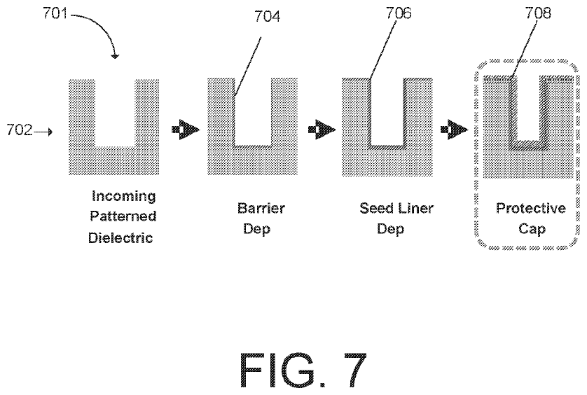

In some embodiments, a sacrificial capping layer is deposited on a seed layer prior to metal fill. An example of such a process is illustrated in FIG. 7. FIG. 7 shows an example of a recessed feature 701 in a patterned dielectric layer 702. Such a substrate can be obtained by patterning the dielectric layer 702 to form the recessed feature 701 by photolithographic methods. A diffusion barrier layer 704 is then deposited in the recessed feature 701 to conformally the recessed feature. The diffusion barrier layer 704 protects the dielectric layer 702 from the diffusion of metal into the dielectric 701. Next, a seed layer 706 is deposited over the diffusion barrier layer 704. The seed layer may include cobalt (Co) and/or copper (Cu) deposited by ALD. For example, in some embodiments, a Co layer can be used to promote adhesion of Cu to the diffusion barrier layer material. In some embodiments, a Cu seed layer may be deposited directly on a diffusion barrier or on a Co layer.

Examples of diffusion barriers include tantalum nitride (TaN), titanium nitride (TiN), tungsten nitride (WN), tungsten carbon nitride (WCN), zinc oxide, and tin oxide. The diffusion barrier material, in some embodiments, is deposited by PVD. For example, TaN or a TiN bi-layer can be deposited over the substrate by PVD using a tantalum or titanium sputter target and a nitrogen-containing process gas.

Any of a metal oxide barrier layer, metal seed layer, and/or metal nitride seed layer may be deposited through ALD and/or CVD. These films can be deposited using a suitable metal-containing reactant and a co-reactant. For example, a WCN layer may be deposited by ALD using a nitrogen-containing organometallic precursor and a reducing gas. Examples of organotungsten precursors to form WCN include bis(tert-butylimino) bis(dimethylamino) tungsten. In another example, zinc oxide can be deposited from diethyl zinc and O₂, and tin oxide can be deposited from tetrakis(dimethylamido)tin and O₂.

In various embodiments, suitable metal-containing reactants may incorporate one or more monodentate ligands such as halides, amides, imides, nitrides, oxides, alkyls, allyls, alkoxides, thiolates, carbenes, phosphines, carbon monoxide, nitriles, isonitriles, alkenes, alkynes, bidentate ligands such as diketonates, ketoiminates, diketiminates, ketoesterates, aminoalkoxides, amidinates, diazadienes, amidates, allyls, di-alkenes, and multidentate ligands such as cyclopentadienyls, tri-alkenes, and other multidentate organic ligands. The metal-containing reactants also include at least one metal, for example the metal that is desired in the deposited material. Suitable metals include those from Groups 3-14 of the periodic table, plus magnesium.

In some cases, a metal-containing reactant used to deposit a metal oxide barrier layer may be an aluminum-containing reactant, a copper-containing reactant, an indium-containing reactant, a magnesium-containing reactant, a manganese-containing reactant, a tin-containing reactant, a zinc-containing reactant, or a combination thereof. In some embodiments, a metal-containing reactant used to deposit a metal seed layer or metal nitride seed layer precursor may be a copper-containing reactant, a cobalt-containing reactant, an iridium-containing reactant, a molybdenum-containing reactant, a palladium-containing reactant, a ruthenium-containing reactant, a tungsten-containing reactant, or a combination thereof. Other metals and metal-containing reactants may be used in some cases.

Example aluminum-containing reactants include, but are not limited to, trimethylaluminum.

Cobalt can be deposited by ALD using a variety of cobalt precursors, where cobalt may be in +1, +2 or +3 oxidation states. Examples of cobalt precursors include cobalt acetate, cobalt acetylacetonates (e.g., cobalt (III) bis(acetylacetonate), cobalt amidinates (e.g., bis(N-t-butyl-N′-ethylpropanimidamidato)cobalt(II),) cobaltocene, and carbonyl-containing cobalt precursors (e.g., cobalt tricarbonyl nitrosyl, and cyclopentadienylcobalt dicarbonyl). An example of a halogen-containing cobalt precursor is CoCl₂(TMEDA), where TMEDA is N,N,N′,N′tetramethylethylenediamine. Further examples of cobalt-containing reactants include, but are not limited to, octacarbonyldicobalt, (2-tert-butylallyl)tricabonylcobalt, (3,3-dimethyl-1-butyne)hexacarbonyldicobalt, bis(1,4-diisopropyl-diazadiene)cobalt, bis(1,4-di-tert-butyl-diazadiene)cobalt, bis(N,N′-diisopropylacetamidinato)cobalt, and bis(N-tert-butyl-N′-ethylpropanimidamidinato)cobalt.

Copper can be deposited by ALD using a variety of copper precursors, where copper may be in +1 or +2 oxidation states. The precursors may be cuprous (copper (I)) compounds such as acetylacetonates, ketoiminates, diiminates, cyclopentadienyl compounds, amidinates, guanidinates or amides; or cupric (copper (II)) compounds such as acetylacetonates, ketominates or aminoalkoxides. Examples of copper precursors include Cu(acac)₂ where acac=acetylacetonato; Cu(thd)₂ where thd=tetrahydrodionato); hexafluoroacetylacteonate-copper-trimethylsilane; cyclopentadienyl (Cp) compounds such as CpCu(CNMe), CpCu(CNCMe₃), CpCuCO, CPCuPR₃ (where R=Me, Et or Ph) and CpCu(CSiMe₃)₂; alkyl or aryl compounds such as MeCu(PPh₃)₃, CuMe, CuCCH(ethynylcopper), CuCMe₃ (methylacetylide copper), (H₂C═CMeCC)Cu(3-methyl-3-buten-1ynylcopper), CuCCPh, C₆H₅Cu (phenyl copper), (Me)₃CCCCu (3,3-dimethyl-1-butynyl) copper, Me₃SiCCCH₂Cu; and other compounds such as CuCN, [Cu (OAc]ₙ (where OAc=acetate), Cu₂Cl₂(butadiene), C₇H₇CuO(2-methoxyphenylcopper), (MeCN)₄CuX (where X is a halide, an alkyl, an amine or a phenyl group), Me₃SiOCu(PMe₃)₃, Cu(C₄H₄S) and Cu-carbene compounds such as those derived from imidazolium. Further examples of copper-containing reactants include, but are not limited to, bis(dimethylamino-2-propoxy)copper, bis(N,N′-di-sec-butylacetamidinate)dicopper, bis(dimethylaminoethoxy)copper, bis(diethylamino-2-propoxy)copper, bis(ethylmethylamino-2-propoxy)copper, and bis(dimethylamino-2-methyl-2-butoxy)copper.

Example indium-containing reactants include, but are not limited to, trimethylindium. Example iridium-containing reactants include, but are not limited to, tris(acetylacetonate)iridium. Example magnesium-containing reactants include, but are not limited to, bis(1,4-di-tert-butyl-diazadiene)magnesium, and bis(ethylcyclopentadienyl)magnesium.

Example manganese-containing reactants include, but are not limited to, bis(cyclopentadienyl)manganese, bis(ethylcyclopentadienyl)manganese, bis(tetramethylcyclopentadienyl)manganese (II), bis(pentamethylcyclopentadienyl)manganese (II), bis(1,4-di-tert-butyl-diazadiene)manganese, bis(bis(trimethylsilylamido))manganese, bis(bis(ethyldimethylsilylamido))manganese, and bis(N,N′-diisopropylpentylamidinato)manganese.

Example molybdenum-containing reactants include, but are not limited to, hexafluoromolybdenum (MoF₆), pentachloromolybdenum (MoCl₅), molybdenum dichloride dioxide (MoO₂Cl₂), molybdenum tetrachloride oxide (MoOCH₄), and molybdenum hexacarbonyl (Mo(CO)₆). In some cases, other molybdenum-containing oxyhalides of the formula MoₓOₓH_{z} may be used, where H is a halogen (fluorine (F), chlorine (Cl), bromine (Br), or iodine (I)) and x, y, and z being any number greater than zero that can form a stable molecule. These include molybdenum tetrafluoride oxide (MoOF₄), molybdenum dibromide dioxide (MoO₂Br₂), and molybdenum oxyiodides MoO₂I and Mo₄O₁₁I. Organo-metallic molybdenum-containing precursors may also be used with examples including molybdenum-containing precursors having cyclopentadienyl ligands. Further examples include precursors of the formula Mo₂Lₙ, wherein each L is independently selected from an amidate ligand, an amidinate ligand, and a guanidinate ligand, where n is 2-5. The Mo₂Lₙ precursor includes a multiple molybdenum-molybdenum bond (such as a double bond or any multiple bond with a bond order of 2-5). Further examples include halide-containing heteroleptic molybdenum compounds (i.e., compounds having different types of ligands). Particular examples of such precursors are compounds that include molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

Example palladium-containing reactants include, but are not limited to, 1-methylallyl(hexafluoroacetylacetonato)-palladium(II) and bis(hexafluoroacetylacetonato)palladium. Example platinum-containing reactants include, but are not limited to, methylcyclopentadienyltrimethylplatinum.

Example rhenium-containing reactants include, but are not limited to, pentachlororhenium. Example ruthenium-containing reactants include, but are not limited to, dodecacarbonyltriruthenium, (2,4-dimethylpentadienyl) ethylcyclopentadienylruthenium, (1-ethyl-1,4-cyclohexadienyl)ethylbenzeneruthenium, bis(ethylcyclopentadienyl)ruthenium, and tetraoxoruthenium. Example tantalum-containing reactants include, but are not limited to, tert-butylimido-tris(dimethylamido)tantalum.

Example tin-containing reactants include, but are not limited to, tetrakis(dimethylamino)tin, tin(II) fluoride, tin(IV) chloride, tin(IV) chloride, tin(IV) bromide, stannane, trimethyltin chloride, dimethyltin dichloride, methyltin trichloride, tetraethyltin, tetramethyltin, dibutyltin diacetate, (dimethylamino)trimethyltin(IV), bis[bis(trimethylsilyl)amino]tin(II), dibutyldiphenyltin, hexaphenylditin(IV), tetraallyltin, tetrakis(diethylamino)tin(IV), tetravineyltin, tin(II) acetylacetonate, tricyclohexyltin hydride, trimethyl(phenylethynyl)tin, trimethyl(phenyl)tin, tetrakis(ethylmethylamino)tin, tin(II)(1,3-bis(1, 1-dimethylethyl)-4,5-dimethyl-(4R,5R)-1,3,2-diazastannolidin-2-ylidene, and N2,N3-di-tert-butyl-butane-2,4-diamino-tin(II).

Example titanium-containing reactants include, but are not limited to, tetrakis(dimethylamido)titanium. Example tungsten-containing reactants include, but are not limited to, hexafluorotungsten, hexachlorotungsten, pentachlorotungsten, and bis(tert-butylimido)bis(dimethylamido)tungsten. Example yttrium-containing reactants include, but are not limited to, tris(isopropylcyclopentadienyl)yttrium. Example zinc-containing reactants include, but are not limited to, dimethylzinc, diethylzinc, diallylzinc, and bis(2-methylallyl)zinc. Other metal-containing reactants known to those of ordinary skill in the art may be used in some embodiments.

For the deposition of metal oxide films such as a metal oxide barrier layer, the metal-containing reactant is paired with an oxygen-containing reactant. Example oxygen-containing reactants include, but are not limited to, water (H₂O), oxygen (O₂), hydrogen peroxide (H₂O₂), ozone (O₃), carbon dioxide (CO₂), and nitrous oxide (N₂O). For the deposition of metal films such as metal seed layers or metal nitride films such as metal nitride seed layer precursors, the metal-containing reactant is paired with a nitrogen-and/or hydrogen-containing reactant. Example nitrogen-and/or hydrogen-containing reactants include, but are not limited to, dinitrogen (N₂), dihydrogen (H₂), hydrazine (N₂H₄), alkylhydrazines, and alkylamines.

In some embodiments, one or more non-reactive gases may be provided during the deposition, for example as a purge gas or as part of a plasma generation gas. Examples of non-reactive gases may include helium, neon, argon, krypton, etc. In some cases, nitrogen may be used.

Deposition of each the diffusion barrier layer and seed layer (or deposition of each layer of a bilayer) may be performed in the same or different chambers or modules as described above. In some embodiments, deposition of these layers is performed in the same vacuum environment.

Next, a sacrificial capping layer 708 is deposited on the seed layer 706 to protect it from oxidation and contamination during ambient exposure. In some embodiments, the sacrificial capping layer 708 is an SRP layer. The SRP layer or other sacrificial capping layer is deposited in the same vacuum environment as the seed layer 706. For example, deposition of the seed layer 706 and the sacrificial capping layer 708 may occur in a substrate processing tool such as substrate processing tool 102a in FIG. 1A.

The recessed feature including the sacrificial capping layer 708 can now be removed from its vacuum environment and exposed to ambient conditions. It may then be transferred to another substrate processing tool such as substrate processing tool 102b. In some embodiments, the sacrificial capping layer is removed by exposure to heat under vacuum as described above. The feature is now ready for copper fill.

In some embodiments, a sacrificial capping layer can include an oxide, nitride, or carbide layer as described above. Such sacrificial capping layers for seed layers may be dissolved for example, by exposure to acid and/or base solutions in an electroplating apparatus. Any of the metal oxide or metal nitride layers described above, for example, may be used.

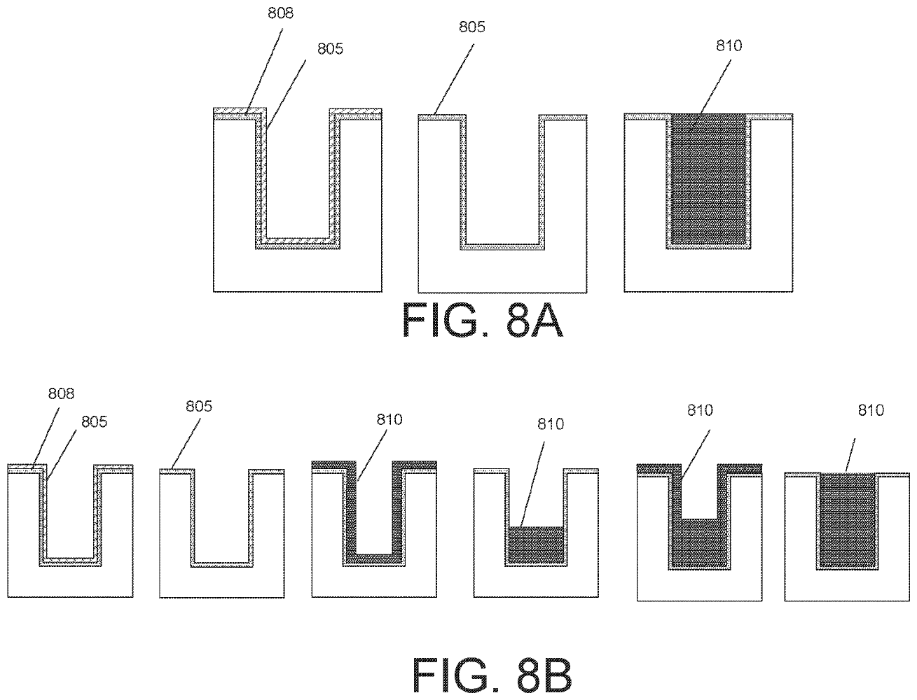

In some embodiments, a sacrificial capping layer is removed from a seed or barrier layer prior to metal fill. FIG. 8A shows an example of a recessed feature 801 in a patterned dielectric layer 802. The feature 801 includes conformal thin film stack 805. Thin film stack 805 may include one or more layers. For example, thin film stack 805 may include a barrier and/or seed layer as described above with reference to FIG. 7. A sacrificial capping layer 808 overlies the thin film stack 805. A substrate including a sacrificial capping layer 808 may be exposed to ambient conditions during a queue time, for example, for between 0.5 to 8 hours. During that time, sacrificial capping layer 808 protects the thin film stack 805.

Once introduced to a substrate processing tool, such as substrate processing tool 102b in FIG. 1A, the sacrificial capping layer is removed by a method as described above. The removal process is in accordance with the thermal budget. This is set by the tolerances of the underlying substrate and can be less than 400° C. for some applications. For some front end of line processes, the thermal budget may be higher.

In some embodiments, the sacrificial capping layer is an SRP film. Examples of removal temperatures can range from 20° C. to 400° C. for SRPs. Purely thermal removal processes can occur at temperatures as low as 120° C. depending on the SRP and as low as room temperature with acids or other catalysts. In an example, a poly(oxymethylene) SRP film is removed between 200° C. and 220° C. under inert conditions in a purely thermal removal process. Once the sacrificial capping layer 808 is removed, the thin film stack 808 is exposed. The feature 801 can then be filled with metal 810 such as copper. Filling the feature with metal may occur in the same semiconductor processing apparatus as capping layer removal, in some embodiments. In such embodiments, it may occur in the same or a different module. In some embodiments, it may occur in a load lock.

FIG. 8B shows an example of a metal fill process that may be implemented in some embodiments. A sacrificial capping layer 808 is removed as described above with respect to FIG. 8A. Then, a first layer of metal 808 is deposited by a PVD process. This first layer is generally conformal. It is then heated to a temperature to allow copper or other metal deposited on the sidewalls to flow down toward the feature bottom.

The initial PVD film of the target fill metal may be deposited as thick as possible without risking the entrapment of a void in the smallest features. The reflow temperature is sufficient to allow some movement of the metal (for example 75°-300° C. for Cu). Capillary forces will cause the metal to preferentially flow into high aspect ratio structures during the reflow. The PVD deposition and reflow operations can be repeated to fill the feature completely with PVD metal or to provide sufficient coverage on the sidewalls and field region for electroplating. The reflow heating can take place in the PVD module (e.g., as shown in FIG. 6) or in a separate chamber on the same semiconductor processing apparatus.

The removal of the sacrificial capping material may occur in the reflow chamber, a PVD chamber, or in a separate chamber. In some embodiments, a semiconductor processing apparatus as shown, for example, at 102b in FIG. 1A includes a PVD module and a reflow module under high vacuum. The capping layer removal may occur in either of these modules or in a third module on the same processing apparatus.

Another example of a process that may be implemented in some embodiments is metal-metal bonding. In an example, a capping layer is deposited on a metal feature to form capped feature. Two capped metal features can be aligned and undergo metal-metal bonding to form a bonded feature. In some examples, the sacrificial capping layer is applied by a processing chamber in the same substrate processing tool that performed electroplating to form the metal feature prior to exposure to ambient conditions. Since the substrate processing tool operates at vacuum, exposure of the substrate to ambient conditions is prevented. For example, an SRP can be deposited by a wet deposition process in the same processing tool used to perform electroplating.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a substrate including a patterned dielectric structure to a first processing apparatus,
depositing one or more conformal layers on the patterned dielectric structure; and
depositing a protective capping layer on the one or more conformal layers, wherein deposition of the one or more conformal layers and deposition of the protective capping layer are performed without exposing the substrate to ambient conditions during or between the deposition operations.

2. The method of claim 1, wherein depositing the one or more conformal layers and depositing the protective capping layer are performed in the first processing apparatus.

3. The method of claim 1, wherein the first processing apparatus is a multi-module apparatus comprising a plurality of modules connected by a substrate transfer chamber.

4. The method of claim 3, wherein deposition of at least one of the one or more conformal layers and deposition of the protective capping layer are performed in the same module of the first processing apparatus.

5. The method of claim 3, wherein deposition at least one of the one or more conformal layers and deposition of the protective capping layer are performed in different modules of the first processing apparatus.

6. The method of claim 1, wherein the one or more conformal layers comprise a diffusion barrier layer.

7. The method of claim 6, wherein the diffusion barrier layer is selected from a tantalum nitride layer, a titanium nitride layer, a tungsten nitride layer, a tungsten carbon nitride layer, a zinc oxide layer, and a tin oxide layer.

8. The method of claim 1, wherein the one or more conformal layers comprise a metal seed layer.

9. The method of claim 8, wherein the metal seed layer is a cobalt layer.

10. (canceled)

11. The method of claim 1, wherein the one or more conformal layers is deposited by atomic layer deposition (ALD).

12. The method of claim 11, wherein the protective capping layer is deposited by chemical vapor deposition (CVD).

13. The method of claim 1, further comprising transferring the substrate from the first processing apparatus after the protective capping layer is deposited.

14. The method of claim 13, further comprising transferring the substrate to a second processing apparatus; and removing the protective capping layer in the second processing apparatus.

15. The method of claim 14, wherein the patterned dielectric structure includes a recessed feature and further comprising filling the recessed feature with metal after removing the protective capping layer.

16. The method of claim 15, wherein filling the recessed feature with metal comprises a physical vapor deposition (PVD) reflow process.

17. The method of claim 1, wherein the protective capping layer is an oxide, a nitride, or a carbide layer.

18. The method of claim 17, wherein the protective capping layer is deposited on a metal seed layer.

19. The method of claim 18, wherein the patterned dielectric structure includes a recessed feature and further comprising filling the recessed feature with metal after removing the protective capping layer.

20. The method of claim 19, wherein filling the recessed feature with metal comprises an electroplating process.

21. The method of claim 20, wherein the removal of the protective capping layer is achieved by thermal desorption above an immersion bath in an electroplating chamber or liquid dissolution in an immersion bath in an electroplating chamber.

22. A method comprising:
providing a substrate including a recessed feature to a first processing apparatus, the substrate comprising a protective capping layer overlying the recessed feature; and
removing the protective capping layer; and filling the recessed feature with metal, wherein the removal of the protective capping layer and filling the recessed feature with metal are performed without exposing the substrate to ambient conditions during or between the removal and filling operations.

23-31. (canceled)

32. A method comprising:
providing a substrate to a first processing apparatus,
depositing one or more conformal layers on the substrate in the first processing apparatus, wherein the one or more layers comprise metal and/or metal nitride layers; and
depositing a protective capping layer on the one or more conformal layers in the first processing apparatus, wherein deposition of the one or more conformal layers and deposition of the protective capping layer are performed without exposing the substrate to ambient conditions during or between the deposition operations, wherein the protective capping layer is a hermetic oxide, nitride, or carbide layer.
